(19) United States
(12) Patent Application Publication
(10) Pub. No.: US 2022/0260910 A1
(43) Pub. Date: Aug. 18, 2022

(54) UNDERLAYER FILM FORMING COMPOSITION FOR LITHOGRAPHY, UNDERLAYER FILM FOR LITHOGRAPHY, AND PATTERN FORMATION METHOD AND PURIFICATION METHOD

(71) Applicant: Mitsubishi Gas Chemical Company, Inc., Tokyo (JP)

(72) Inventors: Hiroaki YAMAMOTO, Hiratsuka-shi, Kanagawa (JP); Takashi MAKINOSHIMA, Hiratsuka-shi, Kanagawa (JP); Masatoshi ECHIGO, Chiyoda-ku, Tokyo (JP)

(21) Appl. No.: 17/614,188

(22) PCT Filed: May 25, 2020
(86) PCT No.: PCT/JP2020/020562

§ 371 Date: Nov. 24, 2021

(30) Foreign Application Priority Data
May 27, 2019 (JP) 2019-098411

(51) Int. Cl. G03F 7/039; G03F 7/32; G03F 7/16; G03F 7/004; G03F 7/38; G03F 7/40

(52) U.S. Cl. CPC G03F 7/0392; G03F 7/322; G03F 7/40; G03F 7/0045; G03F 7/38; G03F 7/162

(57) ABSTRACT

An object of the present invention is to provide a resist underlayer film forming composition for lithography that has features of having excellent smoothing performance on an uneven substrate, good embedding performance into a fine hole pattern, and a smoothed wafer surface after film formation. The object can be solved by the following composition.

An underlayer film forming composition for lithography, comprising:
a: an oligomer having an aralkyl structure represented by the following formula (1-0); and
b: a solvent,

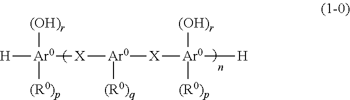

wherein
Ar⁰ represents a phenylene group, a naphthylene group, an anthrylene group, a phenanthrylene group, a pyrylene group, a fluorirene group, a biphenylene group, a diphenylmethylene group, or a terphenylene group;
R⁰ is a substituent on Ar⁰, and each R⁰ is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
X represents a linear or branched alkylene group;
n represents an integer of 1 to 500;
r represents an integer of 1 to 3;
p represents a positive integer; and
q represents a positive integer.

### TECHNICAL FIELD

The present invention relates to an underlayer film forming composition for lithography, an underlayer film for lithography, and a pattern formation method and a purification method.

### BACKGROUND ART

In the production of semiconductor devices, fine processing is practiced by lithography using photoresist materials. In recent years, further miniaturization based on pattern rules has been demanded along with increase in the integration and speed of LSI (large scale integrated circuits). The light source for lithography used upon forming resist patterns has been shifted to ArF excimer laser (193 nm) having a shorter wavelength from KrF excimer laser (248 nm). The introduction of extreme ultraviolet (EUV, 13.5 nm) is also expected.

However, when the miniaturization of resist patterns proceeds, the problem of resolution or the problem of collapse of resist patterns after development arises. Therefore, resists have been desired to have a thinner film. However, if resists merely have a thinner film, it is difficult to obtain the film thicknesses of resist patterns sufficient for substrate processing. Therefore, there has been a need for a process of preparing a resist underlayer film between a resist and a semiconductor substrate to be processed, and imparting functions as a mask for substrate processing to this resist underlayer film in addition to a resist pattern.

Various resist underlayer films for such a process are currently known. For example, in order to achieve a resist underlayer film for lithography having the selectivity of a dry etching rate smaller than that of resists, a resist underlayer film material comprising a polymer having a specific repeat unit has been suggested (see Patent Literature 1). Furthermore, as a material for realizing resist underlayer films for lithography having the selectivity of a dry etching rate smaller than that of semiconductor substrates, a resist underlayer film material comprising a polymer prepared by copolymerizing a repeat unit of an acenaphthylene and a repeat unit having a substituted or unsubstituted hydroxy group has been suggested (see Patent Literature 2).

Meanwhile, as materials having high etching resistance for this kind of resist underlayer film, amorphous carbon underlayer films formed by chemical vapour deposition (CVD) using methane gas, ethane gas, acetylene gas, or the like as a raw material are well known. However, resist underlayer film materials that can form resist underlayer films by a wet process such as spin coating or screen printing have been demanded from the viewpoint of a process.

The present inventors have also proposed an underlayer film forming composition for lithography containing a compound having a specific structure and an organic solvent (see Patent Literature 3) as a material that is excellent in etching resistance, has high heat resistance, and is soluble in a solvent and applicable to a wet process.

### CITATION LIST

### Patent Literature

Patent Literature 1: Japanese Patent Laid-Open No. 2004-271838
Patent Literature 2: Japanese Patent Laid-Open No. 2005-250434
Patent Literature 3: International Publication No. WO 2013/024779

### SUMMARY OF INVENTION

### Technical Problem

However, an underlayer film forming composition for lithography has been required which has high levels of solubility in organic solvents, etching resistance, and resist pattern formability as an underlayer film forming composition at the same time, and further has a feature of having a smoothed wafer surface after film formation.

Therefore, an object of the present invention is to provide a resist underlayer film forming composition for lithography that has features of having excellent smoothing performance on an uneven substrate, good embedding performance into a fine hole pattern, and a smoothed wafer surface after film formation.

### Solution to Problem

The inventors have, as a result of devoted examinations to solve the problems described above, found out that a specific underlayer film forming composition is useful, and reached the present invention.

More specifically, the present invention is as follows.

[1]

An underlayer film forming composition for lithography, comprising:

a: an oligomer having an aralkyl structure represented by the following formula (1-0); and

b: a solvent,

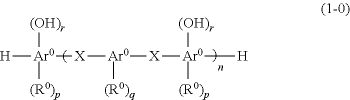

wherein

Ar⁰ represents a phenylene group, a naphthylene group, an anthrylene group, a phenanthrylene group, a pyrylene group, a fluorirene group, a biphenylene group, a diphenylmethylene group, or a terphenylene group;

R⁰ is a substituent on Ar⁰, and each R⁰ is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;

X represents a linear or branched alkylene group;

n represents an integer of 1 to 500;

r represents an integer of 1 to 3;

p represents a positive integer; and

q represents a positive integer.

[2]

The underlayer film forming composition for lithography according to [1], wherein the oligomer having an aralkyl structure represented by the formula (1-0) is represented by the following formula (1-1):

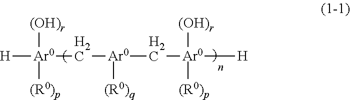

wherein

Ar⁰ represents a phenylene group, a naphthylene group, an anthrylene group, a phenanthrylene group, a pyrylene group, a fluorirene group, a biphenylene group, a diphenylmethylene group, or a terphenylene group;

R⁰ is a substituent on Ar⁰, and each R⁰ is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;

n represents an integer of 1 to 500;

r represents an integer of 1 to 3;

p represents a positive integer; and

q represents a positive integer.

[3]

The underlayer film forming composition for lithography according to [2], wherein the oligomer having an aralkyl structure represented by the formula (1-1) is represented by the following formula (1-2):

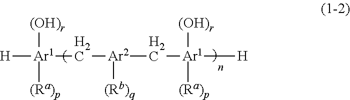

wherein

Ar² represents a phenylene group, a naphthylene group, or a biphenylene group;

Ar¹ represents a naphthylene group or a biphenylene group when Ar² is a phenylene group;

Ar¹ represents a phenylene group, a naphthylene group, or a biphenylene group when Ar² is a naphthylene group or a biphenylene group;

R^{a} is a substituent on Ar¹, and each R^{a} is independently the same or different groups;

R^{a} represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;

R^{b} is a substituent on Ar², and each R^{b} is independently the same or different groups;

R^{b} represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;

n represents an integer of 1 to 500;

r represents an integer of 1 to 3;

p represents a positive integer; and

q represents a positive integer.

[4]

The underlayer film forming composition for lithography according to [3], wherein

Ar² represents a phenylene group, a naphthylene group, or a biphenylene group;

Ar¹ represents a biphenylene group when Ar² is a phenylene group;

Ar¹ represents a phenylene group, a naphthylene group, or a biphenylene group when Ar² is a naphthylene group or a biphenylene group;

R^{a} represents a hydrogen atom or an alkyl group having 1 to 30 carbon atoms and optionally having a substituent; and

R^{b} represents a hydrogen atom or an alkyl group having 1 to 30 carbon atoms and optionally having a substituent.

[5]

The underlayer film forming composition for lithography according to [3] or [4], wherein the oligomer having an aralkyl structure represented by the formula (1-2) is represented by the following formula (2) or formula (3):

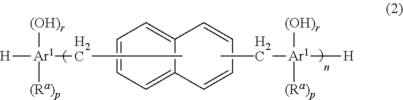

wherein, Ar¹, R^{a}, r, p, and n are as defined in the formula (1-2), and

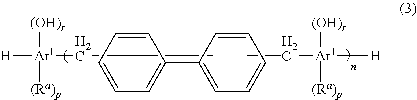

wherein, Ar¹, R^{a}, r, p, and n are as defined in the formula (1-2).
[6]

The underlayer film forming composition for lithography according to [5], wherein the oligomer having an aralkyl structure represented by the formula (2) is represented by the following formula (4):

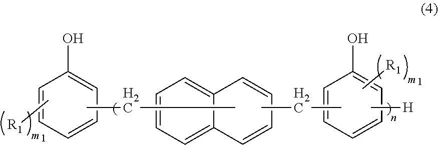

wherein

each R₁ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;

m₁ represents an integer of 1 to 3; and

n represents an integer of 1 to 50.

[7]

The underlayer film forming composition for lithography according to [5], wherein the oligomer having an aralkyl structure represented by the formula (3) is represented by the following formula (5):

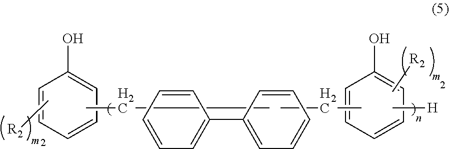

wherein

each R₂ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;

m₂ represents an integer of 1 to 3; and

n represents an integer of 1 to 50.

[8]

The underlayer film forming composition for lithography according to [5], wherein the oligomer having an aralkyl structure represented by the formula (2) is represented by the following formula (6):

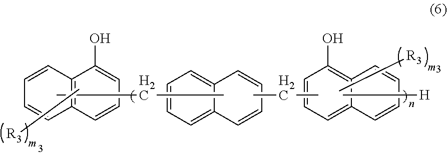

wherein

each R₃ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;

m₃ represents an integer of 1 to 5; and

n represents an integer of 1 to 50.

[9]

The underlayer film forming composition for lithography according to [5], wherein the oligomer having an aralkyl structure represented by the formula (3) is represented by the following formula (7):

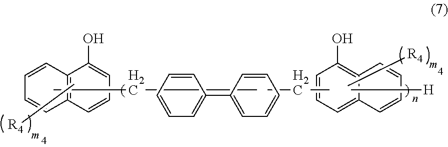

wherein

each R₄ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;

m₄ represents an integer of 1 to 5; and

n represents an integer of 1 to 50.

[10]

The underlayer film forming composition for lithography according to any one of [1] to [9], further comprising an acid generating agent.

[11]

The underlayer film forming composition for lithography according to any one of [1] to [10], further comprising a crosslinking agent.

[12]

An underlayer film for lithography formed by using the underlayer film forming composition for lithography according to any one of [1] to [11].

[13]

A method for forming a resist pattern, comprising the steps of:

forming an underlayer film on a substrate using the underlayer film forming composition for lithography according to any one of the above [1] to [11];

forming at least one photoresist layer on the underlayer film; and

irradiating a predetermined region of the photoresist layer with radiation for development.

[14]

A method for forming a circuit pattern comprising the steps of:

forming an underlayer film on a substrate using the underlayer film forming composition for lithography according to any one of the above [1] to [11];

forming an intermediate layer film on the underlayer film by using a resist intermediate layer film material containing a silicon atom;

forming at least one photoresist layer on the intermediate layer film;

irradiating a predetermined region of the photoresist layer with radiation for development, thereby forming a resist pattern;

etching the intermediate layer film with the resist pattern as a mask;

etching the underlayer film with the obtained intermediate layer film pattern as an etching mask; and

etching the substrate with the obtained underlayer film pattern as an etching mask, thereby forming a pattern on the substrate.

[15]

A purification method comprising the steps of:

obtaining an organic phase by dissolving the oligomer having an aralkyl structure according to any of [1] to [11] in a solvent; and

extracting impurities in the oligomer by bringing the organic phase into contact with an acidic aqueous solution,

wherein

the solvent used in the step of obtaining the organic phase contains a solvent that does not inadvertently mix with water.

### Advantageous Effect of Invention

The present invention can provide a useful underlayer film forming composition for lithography.

### DESCRIPTION OF EMBODIMENTS

Hereinafter, an embodiment of the present invention will be described (hereinafter, also referred to as the “present embodiment”). The embodiments described below are given merely for illustrating the present invention. The present invention is not limited only by these embodiments.

As for structural formulas described in the present specification, for example, when a line indicating a bond to C is in contact with a ring A and a ring B as described below, C is meant to be bonded to any one or both of the ring A and the ring B.

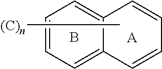

### [Underlayer Film Forming Composition for Lithography]

The underlayer film forming composition of the present embodiment contains:

a: an oligomer having an aralkyl structure represented by the following formula (1-0); and

b: a solvent.

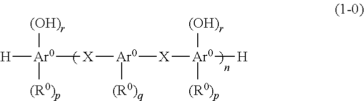

In the oligomer represented by the general formula (1-0), Ar⁰ represents a phenylene group, a naphthylene group, an anthrylene group, a phenanthrylene group, a pyrylene group, a fluorirene group, a biphenylene group, a diphenylmethylene group, or a terphenylene group, and preferably represents a phenylene group, a naphthylene group, an anthrylene group, a phenanthrylene group, a fluorirene group, a biphenylene group, a diphenylmethylene group, or a terphenylene group. R⁰ is a substituent on Ar⁰, and each R⁰ is independently the same or different groups, and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and preferably represents a hydrogen atom or an alkyl group having 1 to 30 carbon atoms and optionally having a substituent.

In the oligomer represented by the general formula (1-0), X represents a linear or branched alkylene group. Specifically, X is a methylene group, an ethylene group, a n-propylene group, an i-propylene group, a n-butylene group, an i-butylene group, or a tert-butylene group, preferably a methylene group, an ethylene group, a n-propylene group, or a n-butylene group, further preferably a methylene group or a n-propylene group, and most preferably a methylene group.

In the oligomer represented by the general formula (1-0), n represents an integer of 1 to 500, and preferably an integer of 1 to 50.

In the oligomer represented by the general formula (1-0), r represents an integer of 1 to 3.

In the oligomer represented by the general formula (1-0), p represents a positive integer. p appropriately varies according to the kind of Ar⁰.

In the oligomer represented by the general formula (1-0), q represents a positive integer. q appropriately varies according to the kind of Ar⁰.

The oligomer represented by the general formula (1-0) is preferably an oligomer represented by the following general formula (1-1).

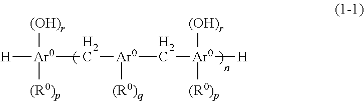

In the oligomer represented by the general formula (1-1), Ar⁰ represents a phenylene group, a naphthylene group, an anthrylene group, a phenanthrylene group, a pyrylene group, a fluorirene group, a biphenylene group, a diphenylmethylene group, or a terphenylene group, and preferably represents a phenylene group, a naphthylene group, an anthrylene group, a phenanthrylene group, a fluorirene group, a biphenylene group, a diphenylmethylene group, or a terphenylene group. R⁰ is a substituent on Ar⁰, and each R⁰ is independently the same or different groups, and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and preferably represents a hydrogen atom or an alkyl group having 1 to 30 carbon atoms and optionally having a substituent.

In the oligomer represented by the general formula (1-1), n represents an integer of 1 to 500, and preferably an integer of 1 to 50.

In the oligomer represented by the general formula (1-1), r represents an integer of 1 to 3.

In the oligomer represented by the general formula (1-1), p represents a positive integer. p appropriately varies according to the kind of Ar⁰.

In the oligomer represented by the general formula (1-1), q represents a positive integer. q appropriately varies according to the kind of Ar⁰.

The oligomer represented by the general formula (1-1) is preferably an oligomer represented by the following general formula (1-2).

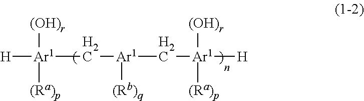

In the oligomer represented by the general formula (1-2), Ar² represents a phenylene group, a naphthylene group, or a biphenylene group, and Ar¹ represents a naphthylene group or a biphenylene group (preferably a biphenylene group) when Ar² is a phenylene group, and Ar¹ represents a phenylene group, a naphthylene group, or a biphenylene group when Ar² is a naphthylene group or a biphenylene group. Specific examples of Ar¹ and Ar² include a 1,4-phenylene group, a 1,3-phenylene group, a 4,4′-biphenylene group, a 2,4′-biphenylene group, a 2,2′-biphenylene group, a 2,3′-biphenylene group, a 3,3′-biphenylene group, a 3,4′-biphenylene group, a 2,6-naphthylene group, a 1,5-naphthylene group, a 1,6-naphthylene group, a 1,8-naphthylene group, a 1,3-naphthylene group, and a 1,4-naphthylene group.

In the oligomer represented by the general formula (1-2), R^{a} is a substituent on Ar¹, and each R^{a} is independently the same or different groups. R^{a} represents hydrogen, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and preferably represents a hydrogen atom or an alkyl group having 1 to 30 carbon atoms and optionally having a substituent. Specific examples of R^{a} include a methyl group, an ethyl group, a n-propyl group, an i-propyl group, a n-butyl group, an i-butyl group, a tert-butyl group, an isomer pentyl group, an isomer hexyl group, an isomer heptyl group, an isomer octyl group, and an isomer nonyl group as the alkyl group, and a phenyl group, an alkylphenyl group, a naphthyl group, an alkylnaphthyl group, a biphenyl group, and an alkylbiphenyl group as the aryl group. R^{a} is preferably a methyl group, an ethyl group, a n-propyl group, a n-butyl group, a n-octyl group, and a phenyl group, further preferably a methyl group, a n-butyl group, a n-octyl group, and most preferably a n-octyl group.

In the oligomer represented by the general formula (1-2), R^{b} is a substituent on Ar², and each R^{b} is independently the same or different groups. R^{b} represents hydrogen, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and preferably represents a hydrogen atom or an alkyl group having 1 to 30 carbon atoms and optionally having a substituent. Specific examples of R^{b} include a methyl group, an ethyl group, a n-propyl group, an isopropyl group, a n-butyl group, an i-butyl group, a tert-butyl group, an isomer pentyl group, an isomer hexyl group, an isomer heptyl group, an isomer octyl group, and an isomer nonyl group as the alkyl group, and a phenyl group, an alkylphenyl group, a naphthyl group, an alkylnaphthyl group, a biphenyl group, and an alkylbiphenyl group as the aryl group. R^{b} is preferably a methyl group, an ethyl group, a n-propyl group, a n-butyl group, a n-octyl group, and a phenyl group, further preferably a methyl group, a n-butyl group, a n-octyl group, and most preferably a n-octyl group.

Among the oligomers represented by the general formula (1-2), a compound represented by the formula (2) or (3) is preferable, and compounds represented by the formulas (4) to (7) are further preferable.

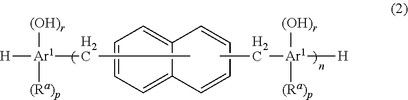

(In the formula (2), Ar¹, R^{a}, r, p, and n are as described above.)

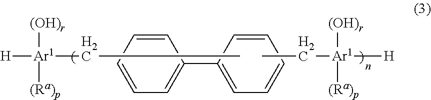

(In the formula (3), Ar¹, R^{a}, r, p, and n are as described above.)

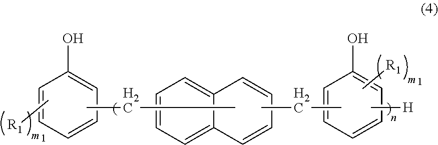

(In the formula (4),

each R₁ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and preferably represents a hydrogen atom or an alkyl group having 1 to 30 carbon atoms and optionally having a substituent;

m₁ represents an integer of 1 to 3; and

n represents an integer of 1 to 50.)

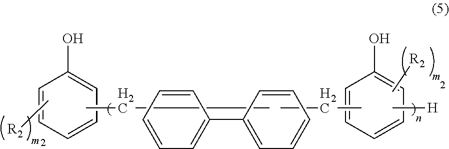

(In the formula (5),

each R₂ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and preferably represents a hydrogen atom or an alkyl group having 1 to 30 carbon atoms and optionally having a substituent;

m₂ represents an integer of 1 to 3; and

n represents an integer of 1 to 50.)

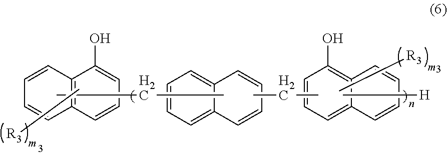

(In the formula (6),

each R₃ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and preferably represents a hydrogen atom or an alkyl group having 1 to 30 carbon atoms and optionally having a substituent;

m₃ represents an integer of 1 to 5; and

n represents an integer of 1 to 50.)

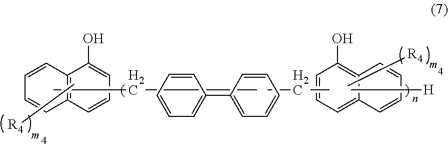

(In the formula (7),

each R₄ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and preferably represents a hydrogen atom or an alkyl group having 1 to 30 carbon atoms and optionally having a substituent;

m₄ represents an integer of 1 to 5; and

n represents an integer of 1 to 50.)

In the compounds of formula (2) to formula (7), the substituent on an aromatic ring may be placed at any position of the aromatic ring.

In the oligomers represented by the general formulas (4), (5), (6), and (7), R₁, R₂, R₃, and R₄ are each independently the same or different groups. R₁, R₂, R₃, and R₄ represent hydrogen, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group, and preferably represents a hydrogen atom or an alkyl group having 1 to 30 carbon atoms and optionally having a substituent. Specific examples of R₁, R₂, R₃, and R₄ include a methyl group, an ethyl group, a n-propyl group, an isopropyl group, a n-butyl group, an i-butyl group, a tert-butyl group, an isomer pentyl group, an isomer hexyl group, an isomer heptyl group, an isomer octyl group, and an isomer nonyl group as the alkyl group, and a phenyl group, an alkylphenyl group, a naphthyl group, an alkylnaphthyl group, a biphenyl group, and an alkylbiphenyl group as the aryl group. R₁, R₂, R₃, and R₄ are preferably a methyl group, an ethyl group, a n-propyl group, a n-butyl group, a n-octyl group, and a phenyl group, further preferably a methyl group, a n-butyl group, a n-octyl group, and most preferably a n-octyl group.

In the present invention, unless otherwise defined, the term “substituted” means that one or more hydrogen atoms in a functional group are substituted with a substituent. Examples of the “substituent” include, but are not particularly limited to, a halogen atom, a hydroxyl group, a cyano group, a nitro group, a thiol group, or a heterocyclic group, an alkyl group having 1 to 30 carbon atoms, an aryl group having 6 to 20 carbon atoms, an alkoxyl group having 1 to 30 carbon atoms, an alkenyl group having 2 to 30 carbon atoms, an alkynyl group having 2 to 30 carbon atoms, an acyl group having 1 to 30 carbon atoms, and an amino group having 0 to 30 carbon atoms.

The alkyl group may be in any aspect of a linear aliphatic hydrocarbon group, a branched aliphatic hydrocarbon group, and a cyclic aliphatic hydrocarbon group.

Specific examples of the compound represented by the above formula (1-0) include compounds represented by the following formulas. However, the compound represented by the above formula (1-0) is not limited to the compounds represented by the following formulas.

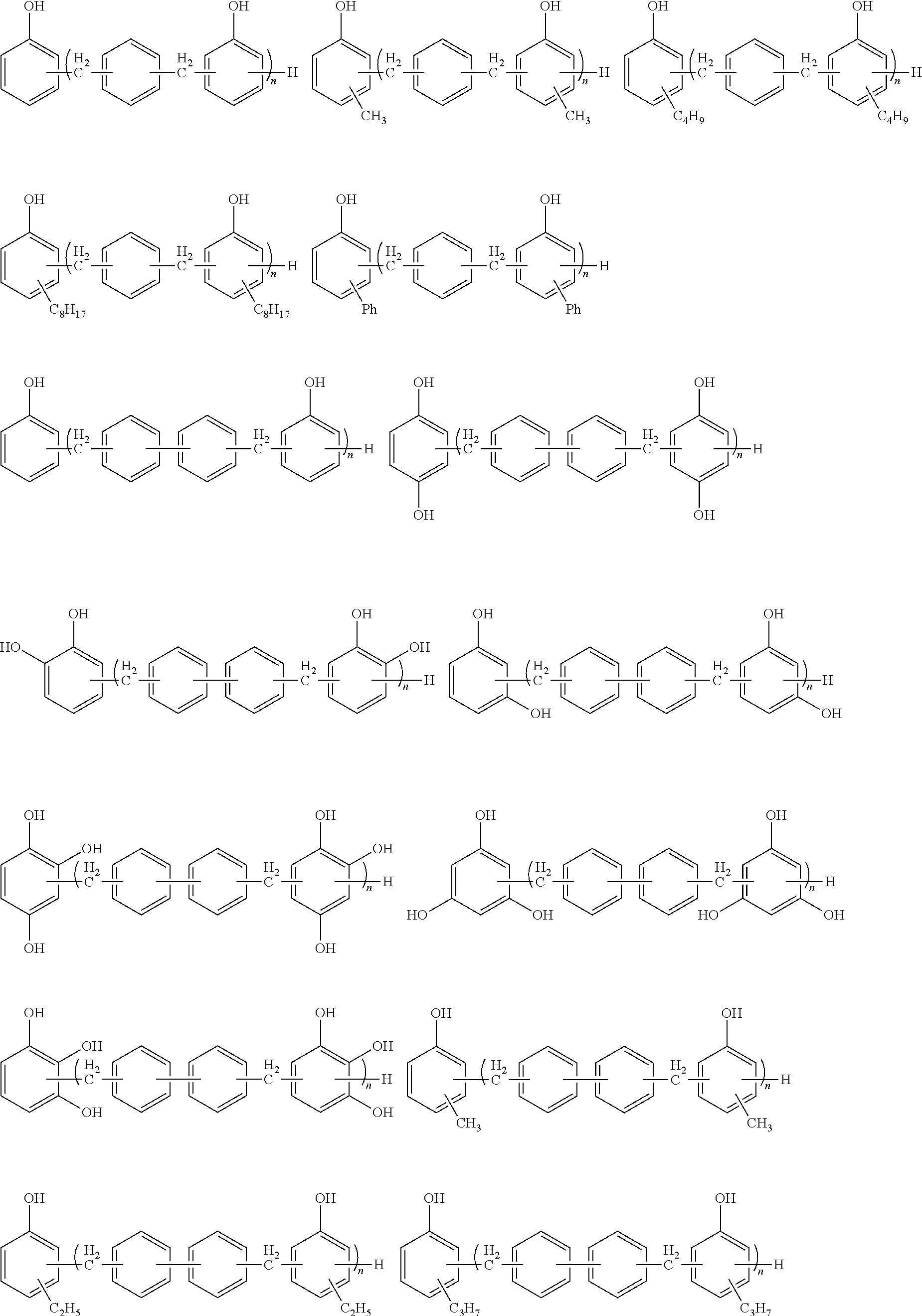

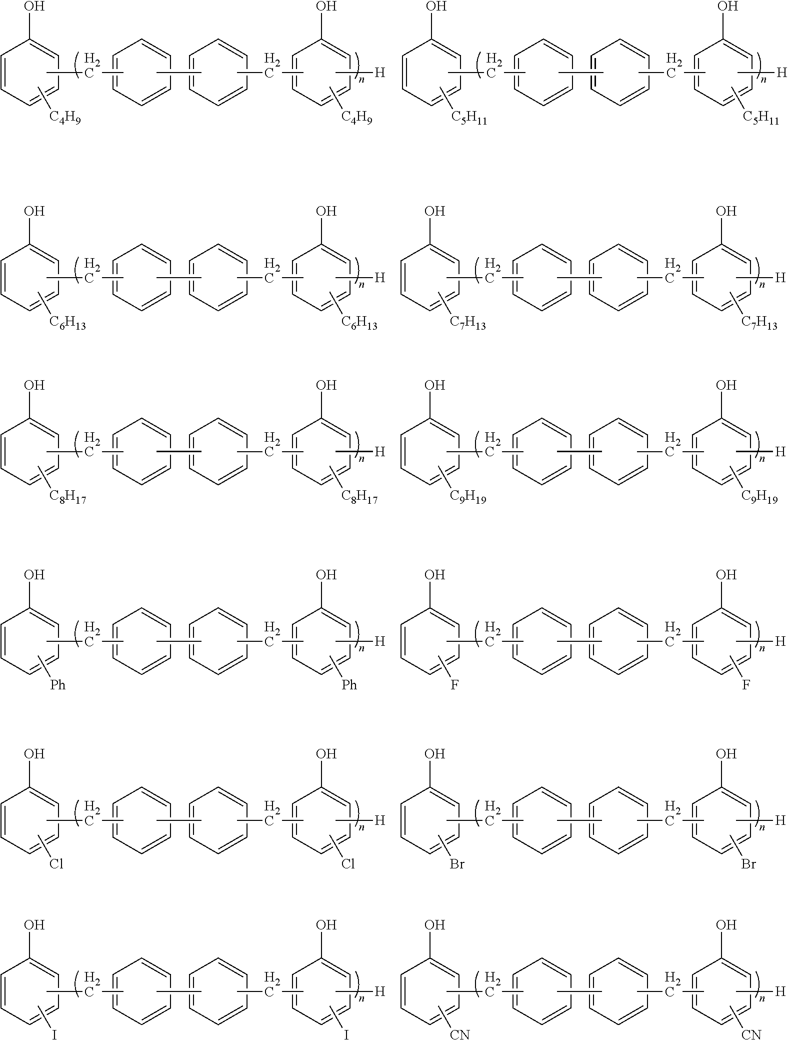

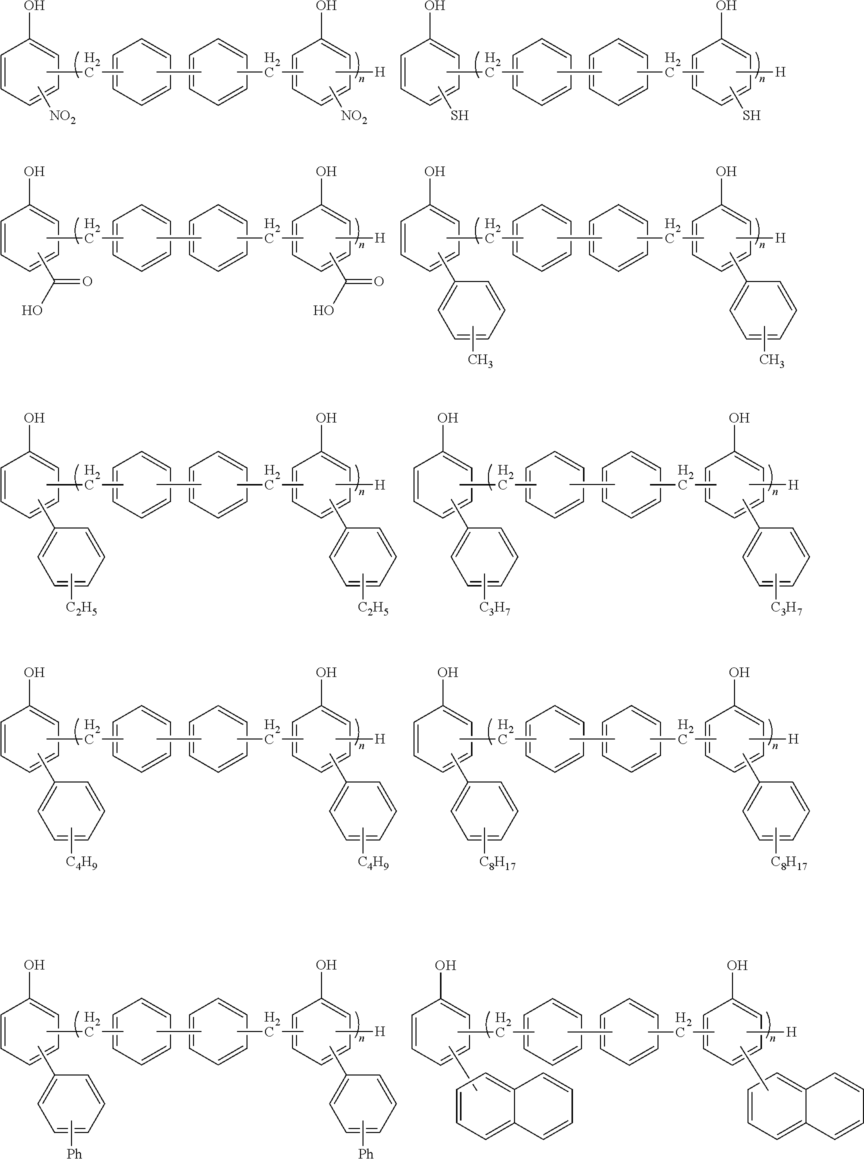

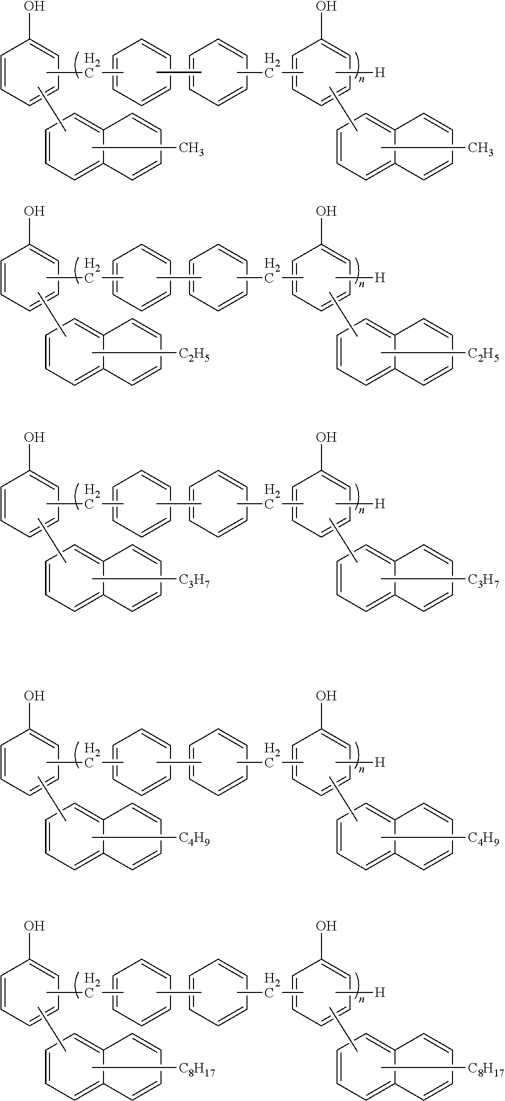

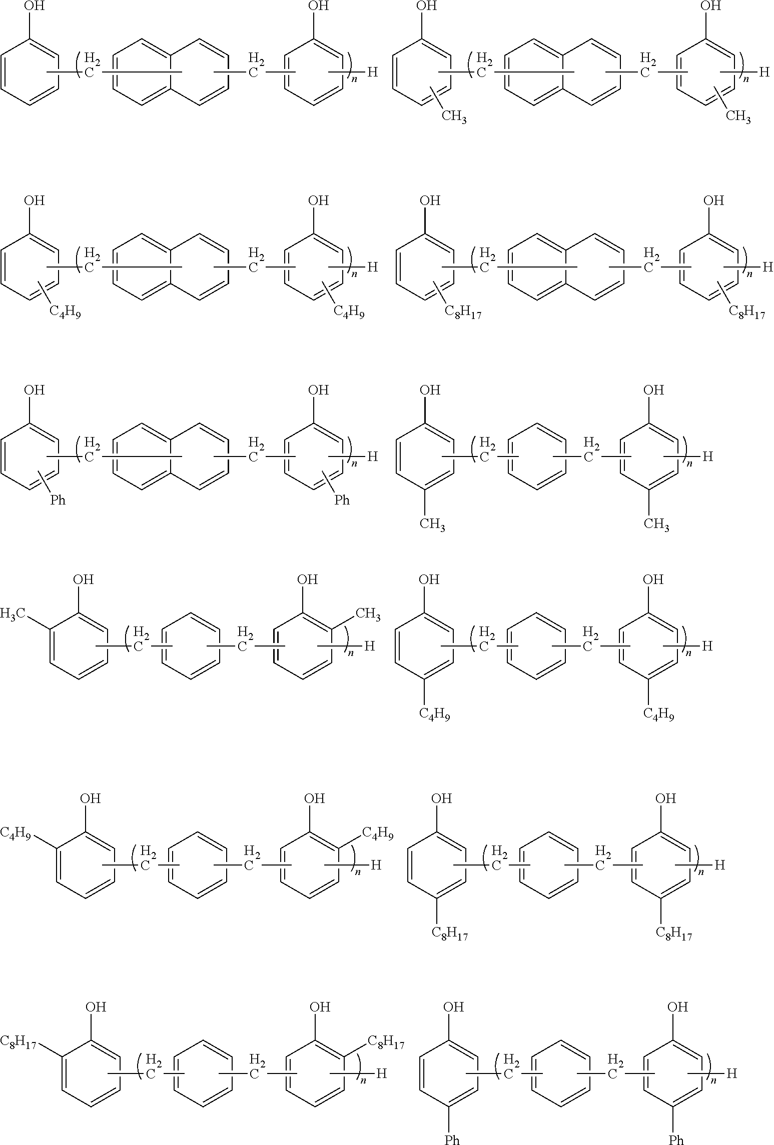

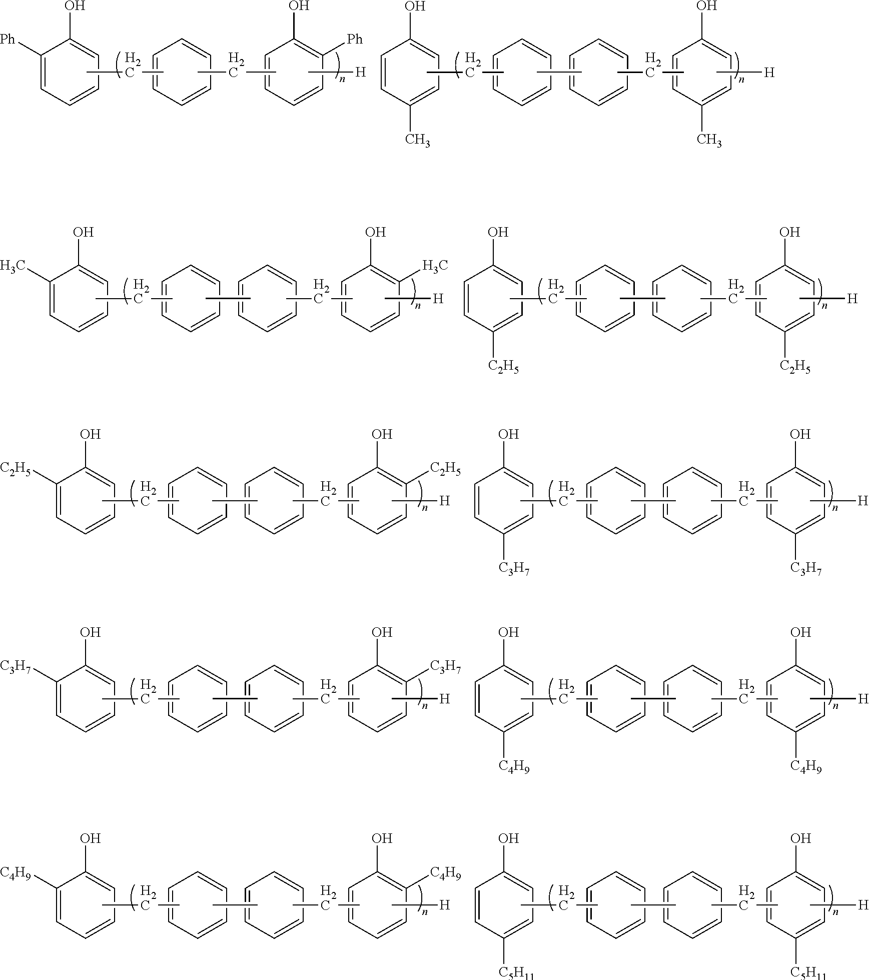

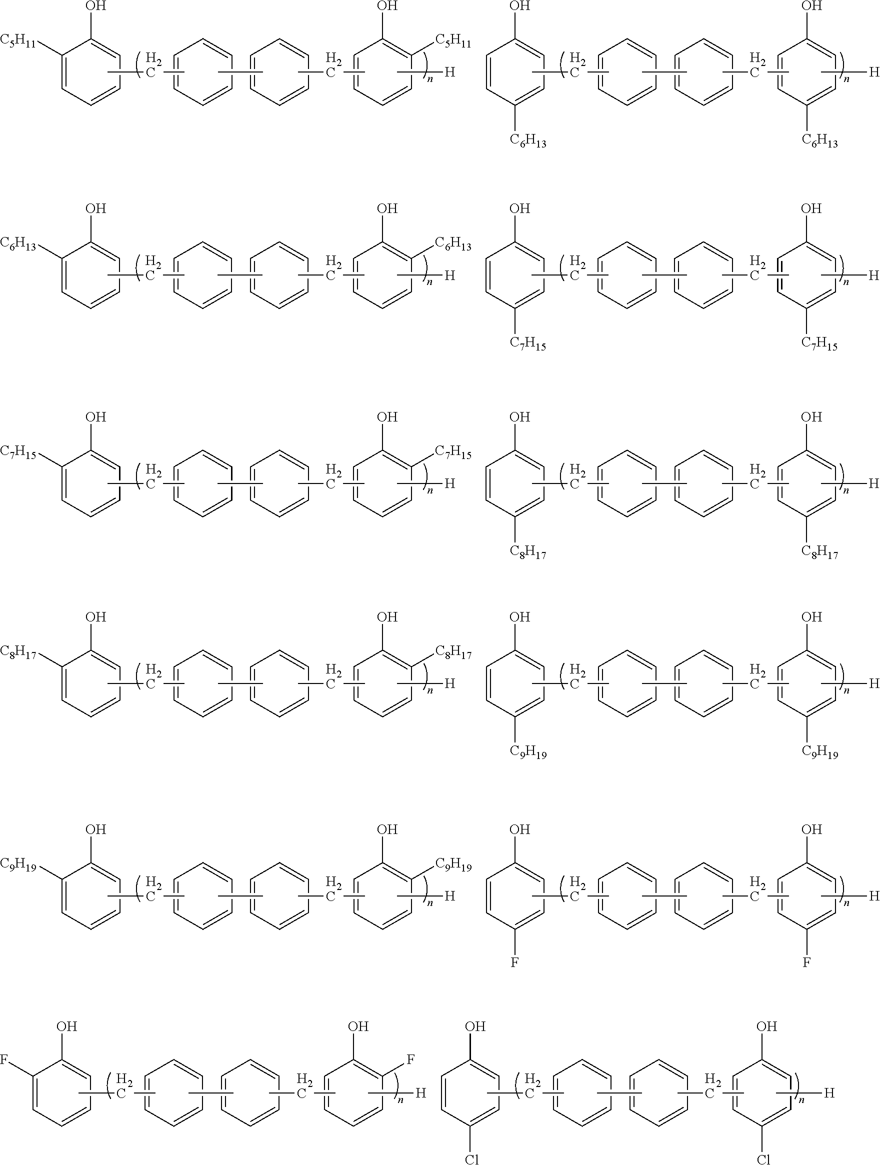

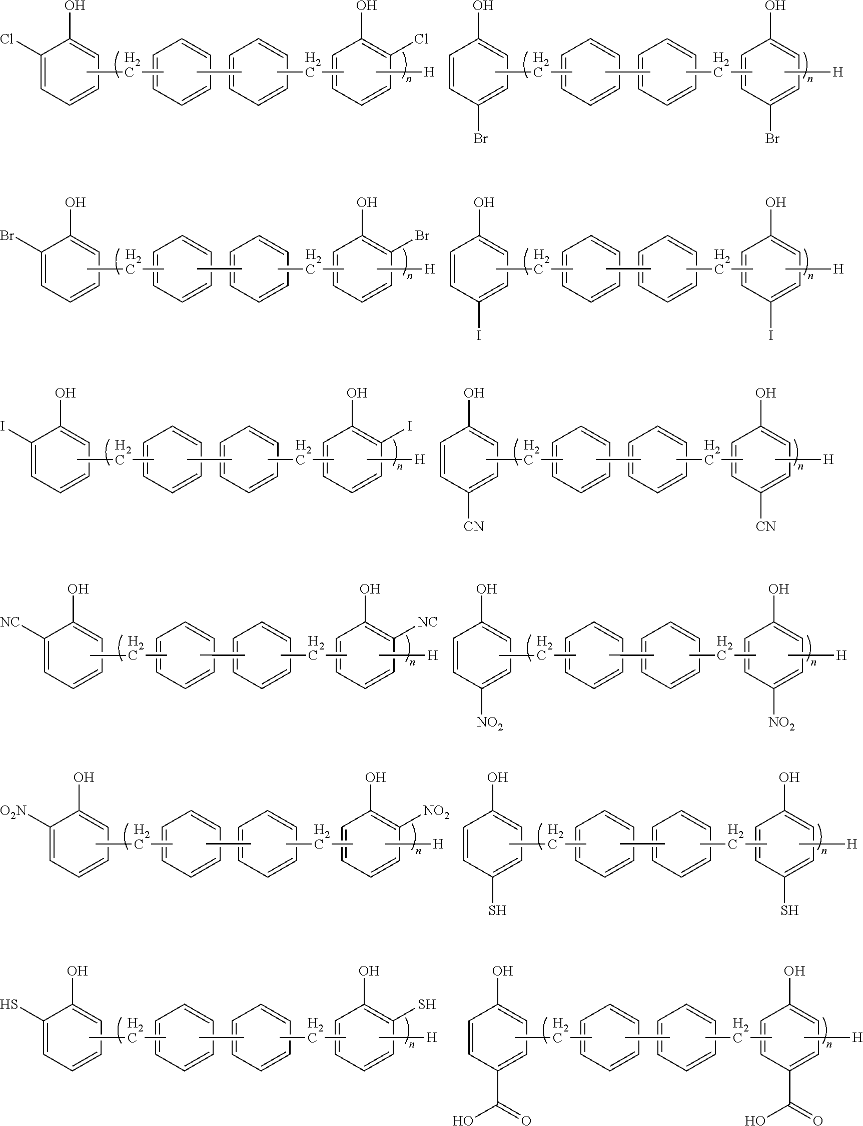

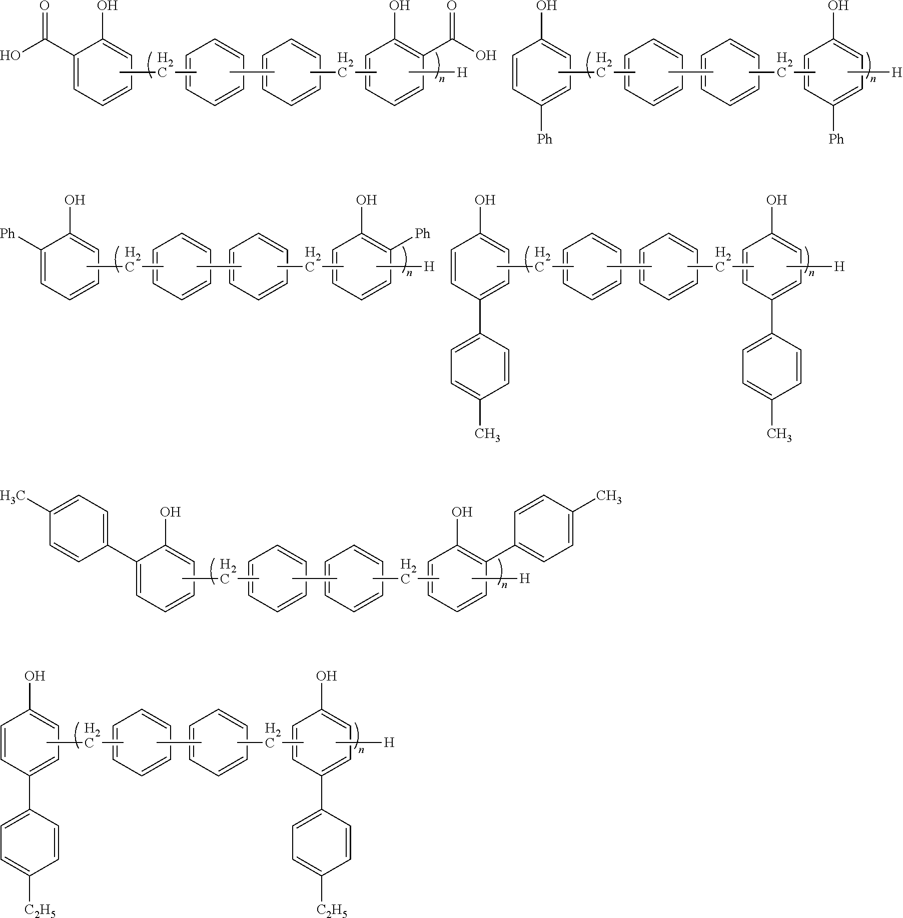

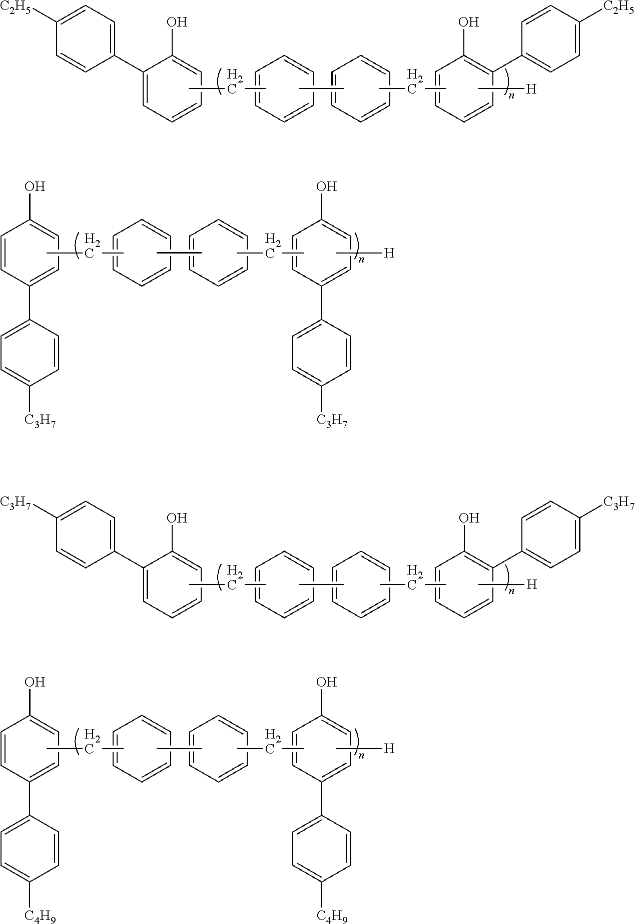

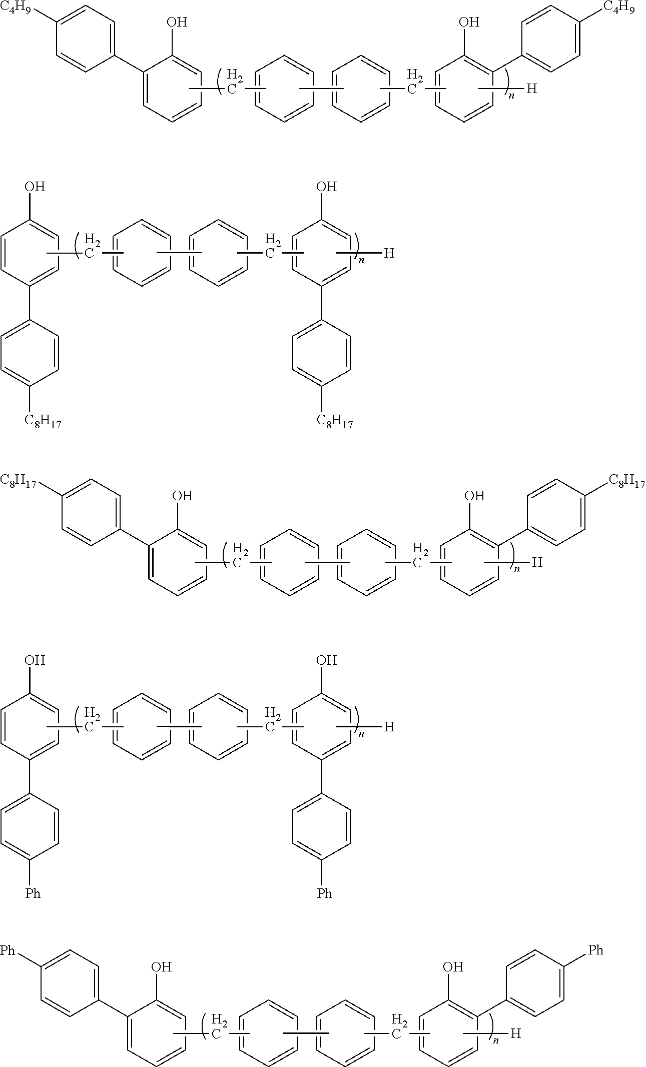

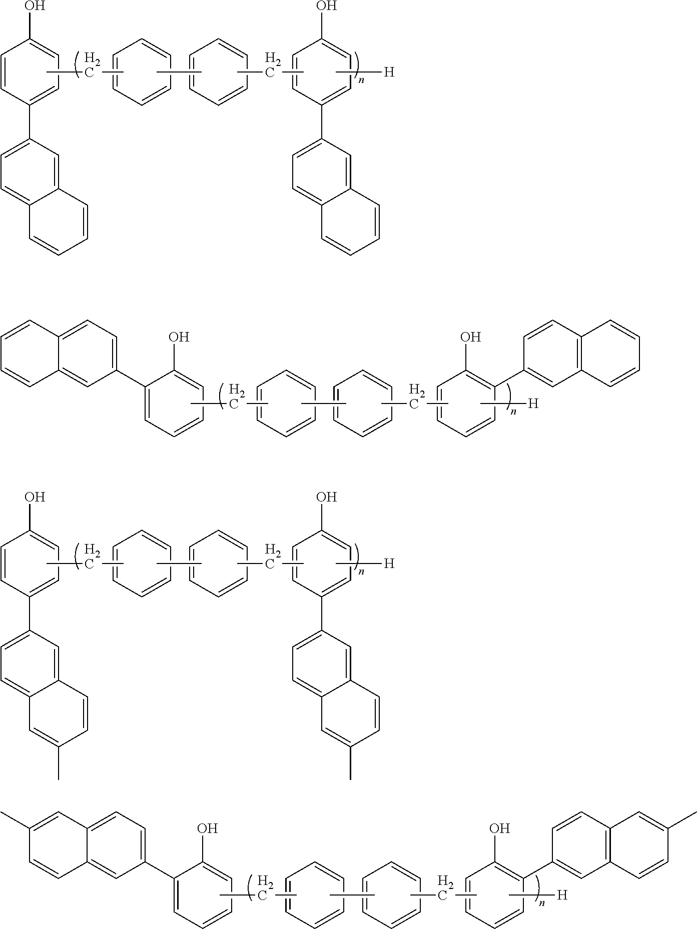

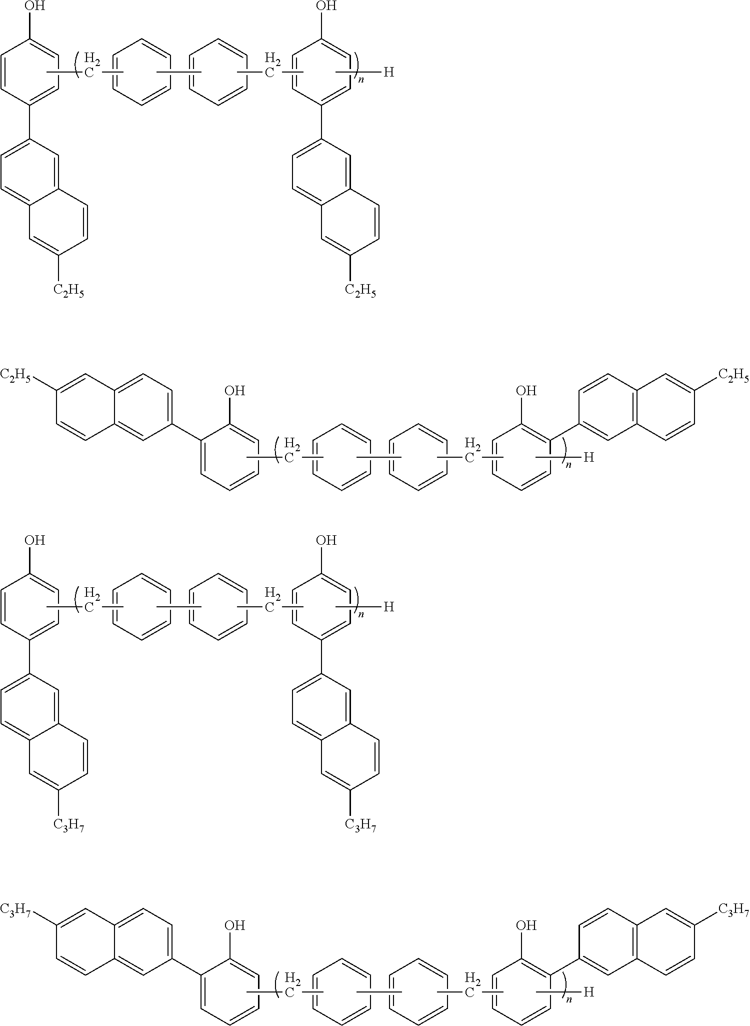

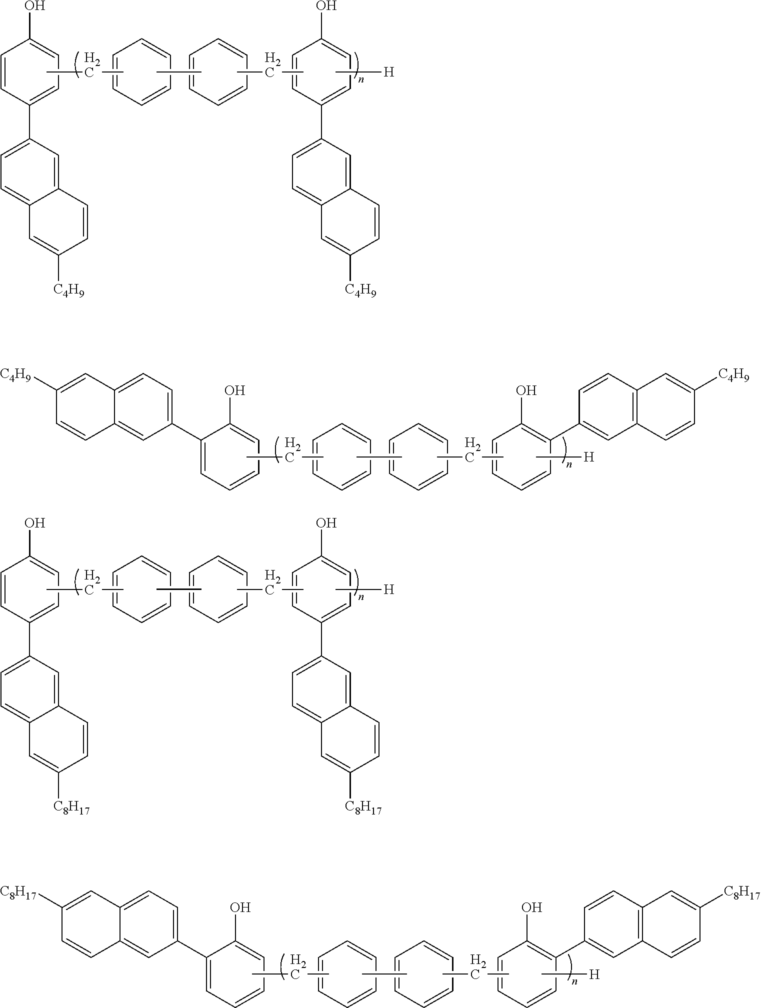

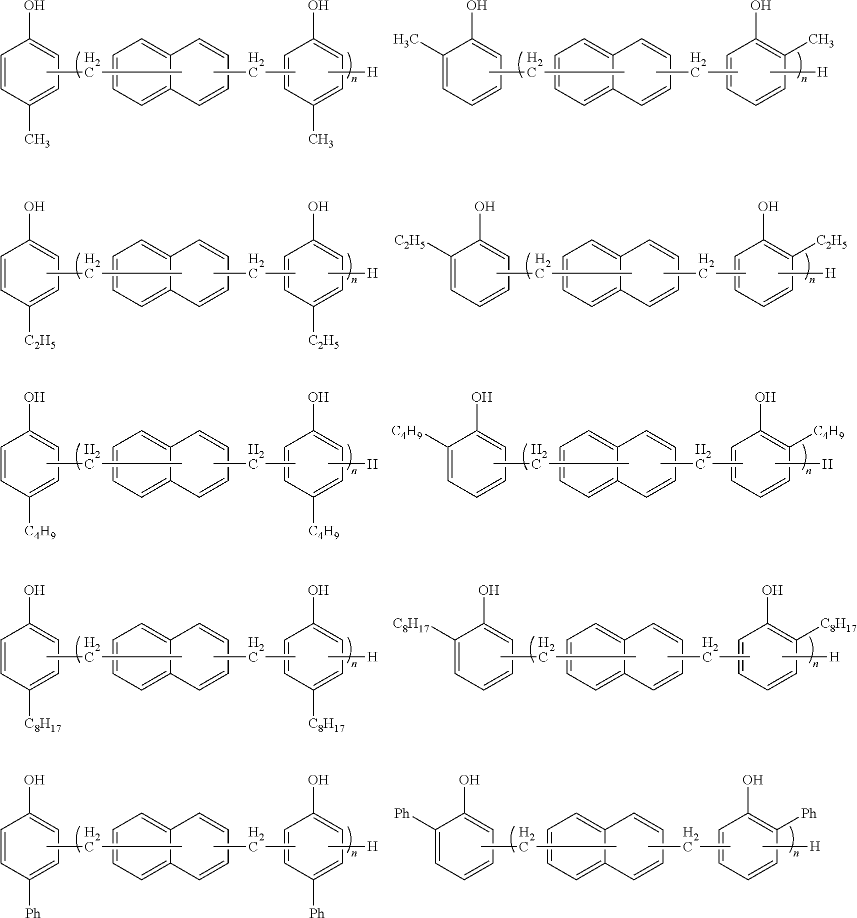

The oligomer represented by the above formula (1-0) has high heat resistance attributed to the aromaticity of its structure, in spite of its relatively low molecular weight, and the underlayer film forming composition for lithography of the present embodiment is thus applicable to a wet process and is excellent in heat resistance and etching resistance. In addition, the underlayer film forming composition for lithography of the present embodiment has an aromatic structure and contains a resin having crosslinkability, and therefore, when it is baked at a high temperature, it causes a cross-linking reaction even on its own, thereby expressing high heat resistance. As a result, deterioration of the film upon baking at a high temperature is suppressed and an underlayer film also excellent in etching resistance to oxygen plasma etching and the like can be formed. Furthermore, even though the underlayer film forming composition for lithography of the present embodiment has an aromatic structure, its solubility in an organic solvent is high, its solubility in a safe solvent is high, and the stability of product quality is good. In addition, the composition for underlayer film for lithography of the present embodiment is also excellent in adhesiveness to a resist layer and a resist intermediate layer film material and can therefore produce an excellent resist pattern.

The molecular weight of the oligomer having an aralkyl structure represented by the above formula (1-0) is not particularly limited, and is preferably Mw=300 to 10000 as a molecular weight in terms of polystyrene, and from the viewpoint of the balance between embedding smoothness and heat resistance, more preferably Mw=500 to 8000, further preferably, Mw=1000 to 6000, and particularly preferably Mw=1000 to 5000. The compound having a structure represented by the above formula (1-0) preferably has dispersibility (weight average molecular weight Mw/number average molecular weight Mn) within the range of 1.1 to 7, and more preferably has dispersibility within the range of 1.1 to 5, from the viewpoint of enhancing crosslinking efficiency while suppressing volatile components during baking. The above Mw, Mn, and dispersibility can be determined by a method described in Examples mentioned later.

Moreover, the oligomer represented by the above formula (1-0) has a relatively low molecular weight and a low viscosity, and therefore facilitates enhancing film smoothness while uniformly and completely filling even the steps of an uneven substrate (particularly having fine space, hole pattern, etc.). As a result, an underlayer film forming composition containing the oligomer represented by the above formula (1-0) has excellent embedding properties and smoothing properties. In addition, the oligomer represented by the above formula (1-0) is a compound that has a relatively high carbon concentration, and can therefore exhibit high etching resistance, as well. The solution viscosity is preferably 0.01 to 1.00 Pa-s (ICI viscosity, 150° C.), and more preferably 0.01 to 0.10 Pa-s, from the viewpoint of embedding properties and smoothing properties. From the similar viewpoint, the softening point (ring and ball method) is preferably 30 to 100° C., and more preferably 30 to 70° C.

The etching resistance of the oligomer having an aralkyl structure represented by the above formula (1-0) is improved particularly when a fused aromatic ring-containing phenol compound is used as a crosslinking agent. This is because a film having high hardness and high carbon density is formed due to an intermolecular interaction between the oligomer represented by the above formula (1-0) having high aromaticity and the crosslinking agent having high planarity.

The embedding properties and smoothing properties of the oligomer having an aralkyl structure represented by the above formula (1-0) are improved particularly when a methylol group-containing phenol compound is used as a crosslinking agent. This is because, since the oligomer represented by the above formula (1-0) and the crosslinking agent have a similar structure, the affinity becomes higher and the viscosity during coating is decreased.

The oligomer having an aralkyl structure represented by the formula (1-0) is an oligomer of an aromatic methylene compound that is formed by a condensation reaction between a phenolic aromatic compound and a crosslinking agent having a methylene bond, and this reaction is carried out in the presence of an acid catalyst.

Examples of the acid catalyst to be used in the above reaction include, without particular limitations, an inorganic acid such as hydrochloric acid, sulfuric acid, phosphoric acid, hydrobromic acid, and hydrofluoric acid; an organic acid such as oxalic acid, malonic acid, succinic acid, adipic acid, sebacic acid, citric acid, fumaric acid, maleic acid, formic acid, p-toluenesulfonic acid, methanesulfonic acid, trifluoroacetic acid, dichloroacetic acid, trichloroacetic acid, trifluoromethanesulfonic acid, benzenesulfonic acid, naphthalenesulfonic acid, and naphthalenedisulfonic acid; a Lewis acid such as zinc chloride, aluminum chloride, iron chloride, and boron trifluoride; and a solid acid such as tungstosilicic acid, tungstophosphoric acid, silicomolybdic acid, and phosphomolybdic acid. These acid catalysts are used alone as one kind or in combination of two or more kinds. Among them, organic acids and solid acids are preferable from the viewpoint of production, and it is preferable to use hydrochloric acid or sulfuric acid from the viewpoint of production such as easy availability and handleability. The amount of the acid catalyst used can be arbitrarily set according to, for example, the kind of the raw materials used and the catalyst used and moreover the reaction conditions and is not particularly limited, but is preferably 0.01 to 100 parts by mass based on 100 parts by mass of the reaction raw materials.

Upon the above reaction, a reaction solvent may be used. Examples of the reaction solvent include, without particular limitations, water, methanol, ethanol, propanol, butanol, tetrahydrofuran, dioxane, ethylene glycol dimethyl ether, and ethylene glycol diethyl ether. These solvents are used alone as one kind or in combination of two or more kinds.

The amount of the solvent used can be arbitrarily set according to, for example, the kind of the raw materials used and the catalyst used and moreover the reaction conditions and is not particularly limited, but is preferably in the range of 0 to 2000 parts by mass based on 100 parts by mass of the reaction raw materials. Furthermore, the reaction temperature in the above reaction can be arbitrarily selected according to the reactivity of the reaction raw materials and is not particularly limited, but is usually within the range of 10 to 200° C.

In order to obtain the oligomer represented by the formula (1-0) of the present embodiment, a higher reaction temperature is preferable. Specifically, the range of 60 to 200° C. is preferable. Although the reaction method is not particularly limited, for example, the raw materials (reactants) and the catalyst may be fed in a batch, or the raw materials (reactants) may be dripped successively in the presence of the catalyst. After the polycondensation reaction terminates, isolation of the obtained compound can be carried out according to a conventional method, and is not particularly limited. For example, by adopting a commonly used approach in which the temperature of the reaction vessel is elevated to 130 to 230° C. in order to remove unreacted raw materials, catalyst, etc. present in the system, and volatile portions are removed at about 1 to 50 mmHg, the oligomer that is the target compound can be obtained.

As preferable reaction conditions, the phenolic aromatic compound is preferably used in the range of 1 mol to 10 mol, based on 1 mol of the crosslinking agent having a methylene bond. When the ratio of the crosslinking agent and the phenolic aromatic compound is within the above range, phenols remained after reaction are decreased and yield is good, and in addition, the mass average molecular weight becomes small and the softening point and the melt viscosity are sufficiently decreased. On the other hand, too low ratio of the crosslinking agent may lead to reduction of the yield, and too high ratio of the crosslinking agent may increase the softening point and the melt viscosity.

The oligomer can be isolated by a publicly known method after the reaction terminates. The oligomer represented by the above formula (1-0) which is the target compound can be obtained by, for example, concentrating the reaction liquid, precipitating the reaction product by the addition of pure water, cooling the reaction liquid to room temperature, then separating the precipitates by filtration, filtering and drying the obtained solid matter, then separating and purifying the solid matter from by-products by column chromatography, and distilling off the solvent, followed by filtration and drying.

Herein, examples of the phenolic aromatic compound used as a raw material of the oligomer having an aralkyl structure of the present embodiment include, but are not particularly limited to, phenol, cresol, dimethylphenol, trimethylphenol, butylphenol, phenylphenol, diphenylphenol, naphthylphenol, resorcinol, methylresorcinol, catechol, butylcatechol, methoxyphenol, methoxyphenol, propylphenol, pyrogallol, thymol, and biphenol, naphthol, methylnaphthol, methoxynaphthol, and dihydroxynaphthalene. The phenolic aromatic compound is preferably phenol, cresol, butylphenol, or diphenylphenol, further preferably phenol, cresol, or butylphenol, and most preferably phenol. From the viewpoint of dissolution stability, pyrene alcohol is less preferable.

Moreover, examples of the crosslinking agent having a methylene bond used as a raw material of the oligomer having an aralkyl structure of the present embodiment include halogenated methyl aromatic compounds or alkoxymethyl aromatic compounds, and specific examples thereof include 1,3-bis(alkoxymethyl)phenyl and 1,3-bis(methyl halide)phenyl (provided that the alkoxy group has 1 to 4 carbon atoms); 4,4′-bis(alkoxymethyl)biphenyl, 2,2′-bis(alkoxymethyl)biphenyl, 2,4′-bis(alkoxymethyl)biphenyl, 4,4′-bis(methyl halide)biphenyl, 2,2′-bis(methyl halide)biphenyl, and 2,4′-bis(methyl halide)biphenyl (provided that the alkoxy group has 1 to 4 carbon atoms); 2,6-bis(alkoxymethyl)naphthalene, 2,7-bis(alkoxymethyl)naphthalene, 1,5-bis(alkoxymethyl)biphenyl, 2,6-bis(methyl halide)naphthalene, 2,7-bis(methyl halide)naphthalene, and 1,8-bis(methyl halide)naphthalene (provided that the alkoxy group has 1 to 4 carbon atoms); paraxylylene glycol dialkyl ether, methaxylylene glycol dialkyl ether, and 1,4-bis(methyl halide)benzene (provided that the alkyl group has 1 to 4 carbon atoms); and 4,4′-bis(alkoxymethyl)diphenylmethylene, 2,2′-bis(alkoxymethyl)diphenylmethylene, 2,4′-bis(alkoxymethyl)diphenylmethylene, 4,4′-bis(methyl halide)diphenylmethylene, 2,2′-bis(methyl halide)diphenylmethylene, and 2,4′-bis(methyl halide)diphenylmethylene (provided that the alkoxy group has 1 to 4 carbon atoms). The crosslinking agent is preferably 1,3-bis(alkoxymethyl)phenyl, 1,3-bis(methyl halide)phenyl, 4,4′-bis(alkoxymethyl)biphenyl, 4,4′-bis(methyl halide)biphenyl, 2,6-bis(alkoxymethyl)naphthalene, 2,6-bis(methyl halide)naphthalene, or 4,4′-bis(alkoxymethyl)diphenylmethylene, further preferably 1,3-bis(methyl halide)phenyl, 4,4′-bis(alkoxymethyl)biphenyl, 4,4′-bis(methyl halide)biphenyl, or 2,6-bis(methyl halide)naphthalene, and most preferably 4,4′-bis(methyl halide)biphenyl. From the viewpoint of improving smoothing properties, biphenyl raw materials which increase the free volume of molecule and reduce the viscosity are more preferable than naphthalene raw materials which have fused aromatic rings. These crosslinking agents may be used alone as one kind or may be used in combination of two or more kinds.

The oligomer represented by the formula (1-0) mentioned above preferably has high solubility in a solvent from the viewpoint of easier application to a wet process, etc. More specifically, in the case of using 1-methoxy-2-propanol (PGME) and/or propylene glycol monomethyl ether acetate (PGMEA) as a solvent, the oligomer preferably has a solubility of 10% by mass or more in the solvent. Here, the solubility in PGME and/or PGMEA is defined as “mass of the resin/(mass of the resin+mass of the solvent)×100 (% by mass)”.

For example, 10 g of the oligomer represented by the above formula (1-0) is evaluated as being dissolved in 90 g of PGMEA when the solubility of the oligomer represented by the formula (1-0) in PGMEA is “10% by mass or more”; 10 g of the oligomer is evaluated as being not dissolved in 90 g of PGMEA when the solubility is “less than 10% by mass”.

The composition of the present embodiment contains the oligomer of the present embodiment, and thus is applicable to a wet process, and is excellent in heat resistance and smoothing properties. Furthermore, the composition of the present embodiment contains the oligomer of the present embodiment and can therefore form a film for lithography that is prevented from deteriorating during high temperature baking and is excellent in etching resistance against oxygen plasma etching or the like. Furthermore, the composition of the present embodiment is also excellent in adhesiveness to a resist layer and can therefore form an excellent resist pattern. Therefore, the composition of the present embodiment is suitably used for forming an underlayer film.

### [Method for Purifying Film Forming Material for Lithography]

The film forming material for lithography (oligomer) can be purified by washing with an acidic aqueous solution. The above purification method comprises a step in which the film forming material for lithography is dissolved in an organic solvent that does not inadvertently mix with water to obtain an organic phase, the organic phase is brought into contact with an acidic aqueous solution to carry out extraction treatment (a first extraction step), thereby transferring metals contained in the organic phase containing the film forming material for lithography and the organic solvent to an aqueous phase, and then, the organic phase and the aqueous phase are separated. According to the purification, the contents of various metals in the film forming material for lithography of the present invention can be reduced remarkably.

The organic solvent that does not inadvertently mix with water is not particularly limited, but is preferably an organic solvent that is safely applicable to semiconductor manufacturing processes. Normally, the amount of the organic solvent used is approximately 1 to 100 times by mass relative to the compound used.

Specific examples of the organic solvent to be used include those described in International Publication No. WO 2015/080240. Among these, toluene, 2-heptanone, cyclohexanone, cyclopentanone, methyl isobutyl ketone, propylene glycol monomethyl ether acetate, ethyl acetate, and the like are preferable, and cyclohexanone and propylene glycol monomethyl ether acetate are particularly preferable. These organic solvents can be each used alone, and can be used as a mixture of two or more kinds.

The above acidic aqueous solution is appropriately selected from aqueous solutions in which generally known organic or inorganic compounds are dissolved in water. For example, examples thereof include those described in International Publication No. WO 2015/080240. These acidic aqueous solutions can be each used alone, or can also be used as a combination of two or more kinds. Examples of the acidic aqueous solution may include, for example, an aqueous mineral acid solution and an aqueous organic acid solution. Examples of the aqueous mineral acid solution may include, for example, an aqueous solution comprising one or more selected from the group consisting of hydrochloric acid, sulfuric acid, nitric acid, and phosphoric acid. Examples of the aqueous organic acid solution may include, for example, an aqueous solution comprising one or more selected from the group consisting of acetic acid, propionic acid, oxalic acid, malonic acid, succinic acid, fumaric acid, maleic acid, tartaric acid, citric acid, methanesulfonic acid, phenolsulfonic acid, p-toluenesulfonic acid, and trifluoroacetic acid. Moreover, as the acidic aqueous solution, aqueous solutions of sulfuric acid, nitric acid, and a carboxylic acid such as acetic acid, oxalic acid, tartaric acid, and citric acid are preferable, aqueous solutions of sulfuric acid, oxalic acid, tartaric acid, and citric acid are further preferable, and an aqueous solution of oxalic acid is particularly preferable. It is considered that a polyvalent carboxylic acid such as oxalic acid, tartaric acid, and citric acid coordinates with metal ions and provides a chelating effect, and thus is capable of removing more metals. In addition, as the water used herein, water, the metal content of which is small, such as ion exchanged water, is preferable according to the purpose of the present invention.

The pH of the acidic aqueous solution is not particularly limited, but when the acidity of the aqueous solution is too high, it may have a negative influence on the used oligomer, which is not preferable. Normally, the pH range is about 0 to 5, and is more preferably about pH 0 to 3.

The amount of the acidic aqueous solution used is not particularly limited, but when the amount is too small, it is required to increase the number of extraction treatments for removing metals, and on the other hand, when the amount of the aqueous solution is too large, the entire fluid volume becomes large, which may cause operational problems. Normally, the amount of the aqueous solution used is 10 to 200 parts by mass and preferably 20 to 100 parts by mass relative to the solution of the film forming material for lithography.

By bringing the acidic aqueous solution into contact with a solution (B) containing the film forming material for lithography and the organic solvent that does not inadvertently mix with water, metals can be extracted.

The temperature at which the above extraction treatment is carried out is generally in the range of 20 to 90° C., and preferably 30 to 80° C. The extraction operation is carried out, for example, by thoroughly mixing the solution (B) and the acidic aqueous solution by stirring or the like and then leaving the obtained mixed solution to stand still. Thereby, metals contained in the solution containing the oligomer and the organic solvent are transferred to the aqueous phase. Also, by this operation, the acidity of the solution is lowered, and the degradation of the oligomer can be suppressed.

After the extraction treatment, the mixed solution is separated into a solution phase containing the oligomer and the organic solvent and an aqueous phase, and the solution containing the organic solvent is recovered by decantation or the like. The time for leaving the mixed solution to stand still is not particularly limited, but when the time for leaving the mixed solution to stand still is too short, separation of the solution phase containing the organic solvent and the aqueous phase becomes poor, which is not preferable. Normally, the time for leaving the mixed solution to stand still is 1 minute or longer, more preferably 10 minutes or longer, and still more preferably 30 minutes or longer. In addition, while the extraction treatment may be carried out only once, it is also effective to repeat mixing, leaving-to-stand-still, and separating operations multiple times.

When such an extraction treatment is carried out using the acidic aqueous solution, after the treatment, it is preferable to further subjecting the recovered organic phase that has been extracted from the aqueous solution and contains the organic solvent to an extraction treatment with water (a second extraction step). The extraction operation is carried out by thoroughly mixing the organic phase and water by stirring or the like and then leaving the obtained mixed solution to stand still. The resultant mixed solution is separated into a solution phase containing the oligomer and the organic solvent and an aqueous phase, and thus the solution phase is recovered by decantation or the like. In addition, as the water used herein, water, the metal content of which is small, such as ion exchanged water, is preferable according to the purpose of the present invention. While the extraction treatment may be carried out only once, it is also effective to repeat mixing, leaving-to-stand-still, and separating operations multiple times. The proportions of both used in the extraction treatment and the temperature, time, and other conditions are not particularly limited, and may be the same as those of the previous contact treatment with the acidic aqueous solution.

Water that is unwantedly present in the thus-obtained solution containing the film forming material for lithography and the organic solvent can be easily removed by performing vacuum distillation or a like operation. Also, if required, the concentration of the compound can be regulated to be any concentration by adding an organic solvent.

A method for only obtaining the film forming material for lithography from the obtained solution containing the organic solvent can be carried out through a publicly known method such as reduced-pressure removal, separation by reprecipitation, and a combination thereof. Publicly known treatments such as concentration operation, filtration operation, centrifugation operation, and drying operation can be carried out if required.

The underlayer film forming composition of the present embodiment contains a solvent in addition to the oligomer of the present embodiment. In addition, the underlayer film forming composition of the present embodiment may contain a crosslinking agent, a crosslinking promoting agent, an acid generating agent, a basic compound, and a further component, if required. These components will be described below.

### [Solvent]

The underlayer film forming composition according to the present embodiment contains a solvent. The solvent is not particularly limited as long as it is a solvent that can dissolves the oligomer of the present embodiment. Here, the oligomer of the present embodiment has excellent solubility in an organic solvent, as mentioned above, and therefore, various organic solvents are suitably used. Specific solvent include a solvent described in International Publication No. WO 2018/016614.

Among the solvents, from the viewpoint of safety, one or more selected from the group consisting of cyclohexanone, propylene glycol monomethyl ether, propylene glycol monomethyl ether acetate, ethyl lactate, methyl hydroxyisobutyrate and anisole are preferable.

The content of the solvent is not particularly limited and is preferably 100 to 10,000 parts by mass based on 100 parts by mass of the oligomer of the present embodiment, more preferably 200 to 5,000 parts by mass, and still more preferably 200 to 1,000 parts by mass, from the viewpoint of solubility and film formation.

### [Crosslinking Agent]

The underlayer film forming composition of the present embodiment may contain a crosslinking agent from the viewpoint of, for example, suppressing intermixing.

Examples of the crosslinking agent include, but are not particularly limited to, a phenol compound, an epoxy compound, a cyanate compound, an amino compound, a benzoxazine compound, an acrylate compound, a melamine compound, a guanamine compound, a glycoluril compound, a urea compound, an isocyanate compound, and an azide compound. Specific examples of these crosslinking agents include those described in International Publication No. 2018/016614 and International Publication No. 2013/024779. These crosslinking agents are used alone as one kind or in combination of two or more kinds. Among these, a fused aromatic ring-containing phenol compound is more preferable, from the viewpoint of improving etching resistance. Also, a methylol group-containing phenol compound is more preferable, from the viewpoint of improving smoothing properties.

The methylol group-containing phenol compound used as a crosslinking agent is preferably a compound represented by the following formula (11-1) or (11-2), from the viewpoint of improving smoothing properties.

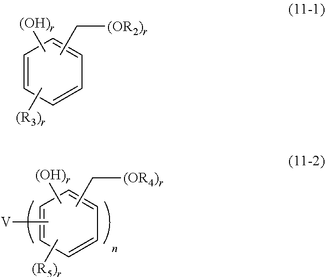

In the crosslinking agent represented by the general formula (11-1) or (11-2), V is a single bond or a n-valent organic group; R₂ and R₄ are each independently a hydrogen atom or an alkyl group having 1 to 10 carbon atoms; and R3 and R5 are each independently an alkyl group having 1 to 10 carbon atoms or an aryl group having 6 to 40 carbon atoms. n is an integer of 2 to 10, and each r is independently an integer of 0 to 6.

Specific examples of the compound represented by the general formula (11-1) or (11-2) include compounds represented by the following formulas. However, the general formula (11-1) or (11-2) is not limited to the compounds represented by the following formulas.

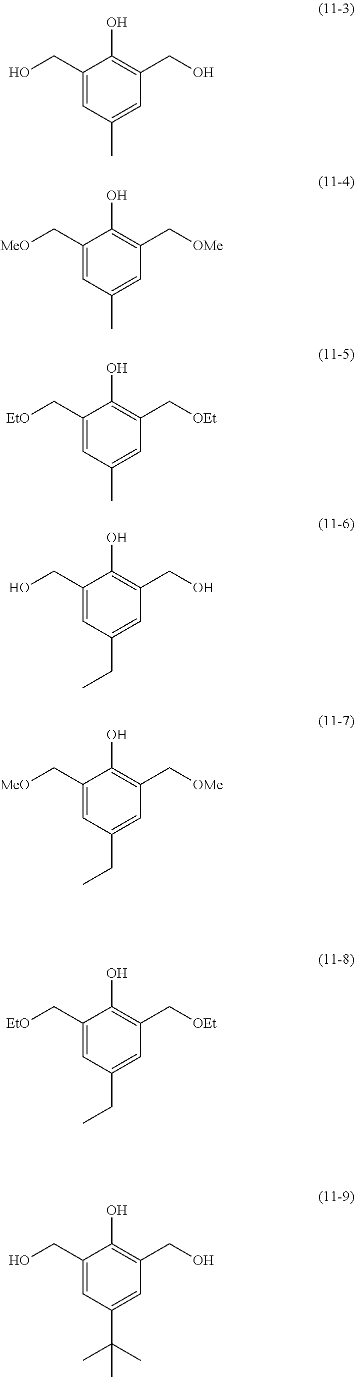

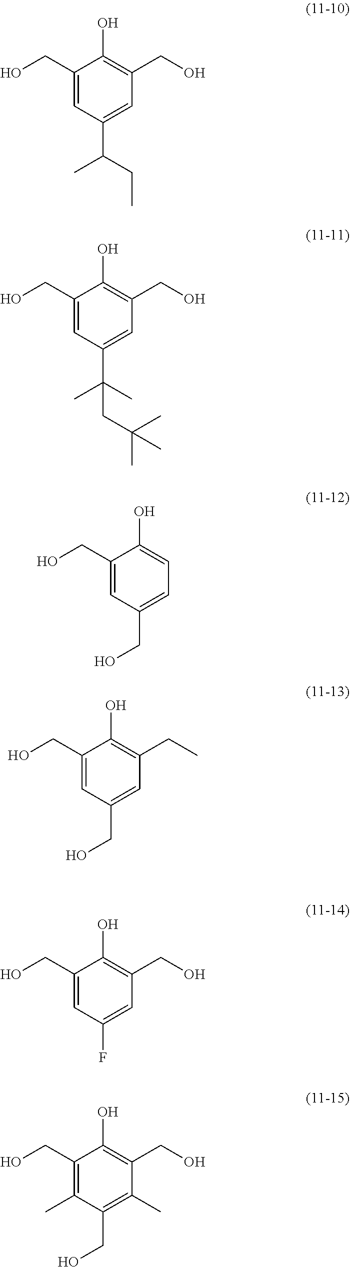

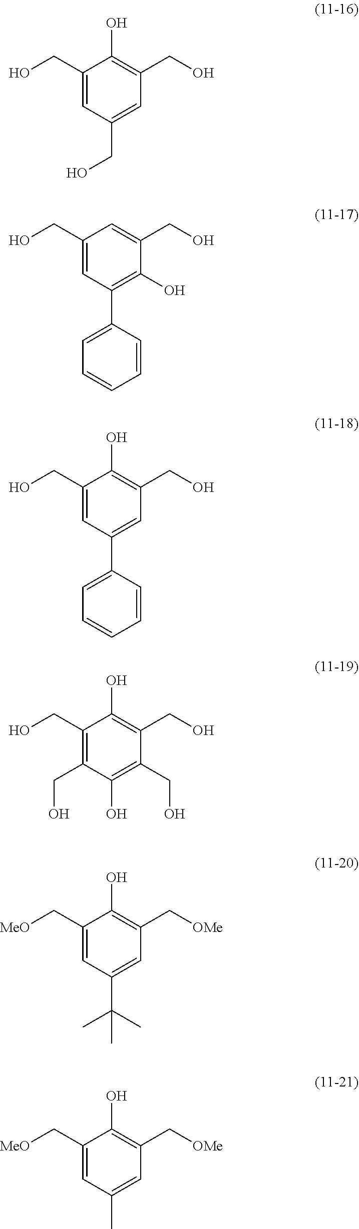

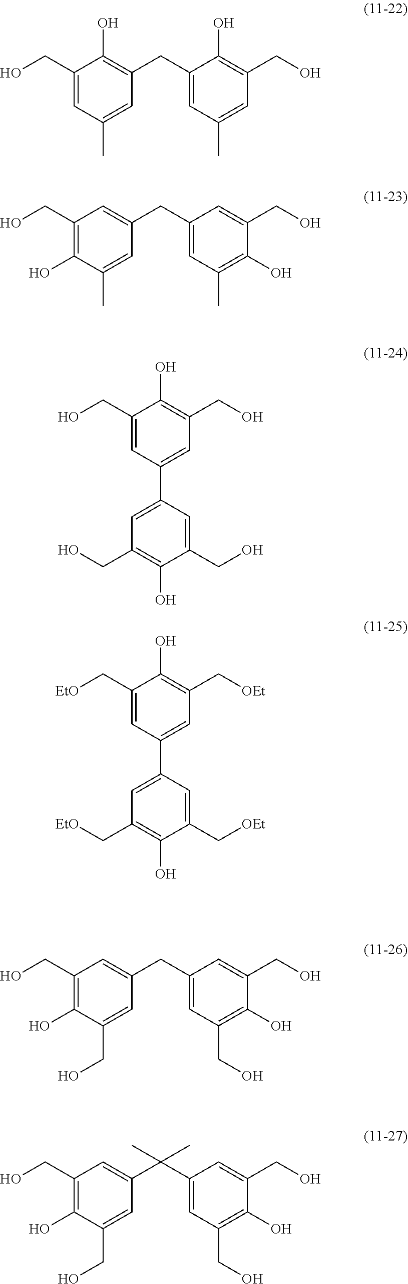

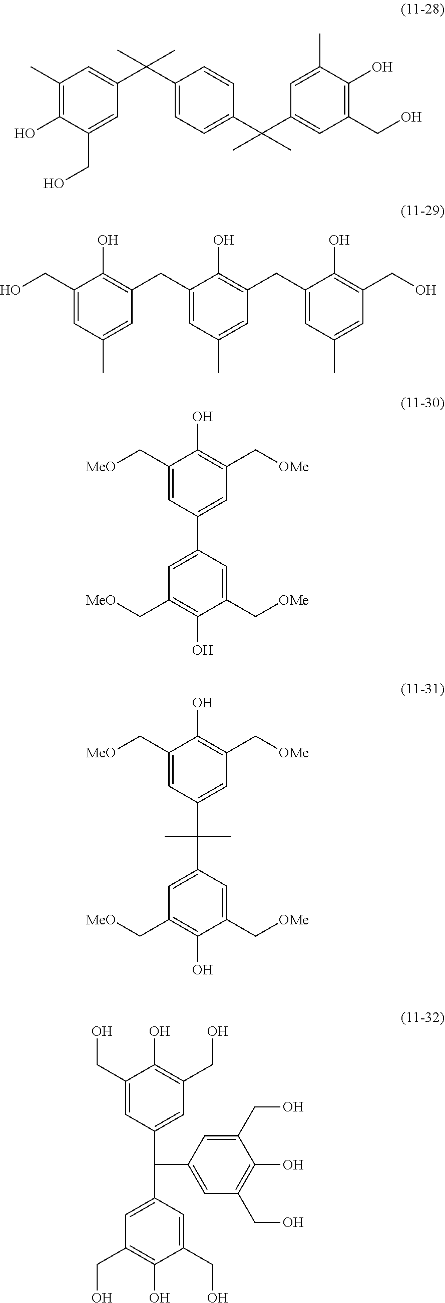

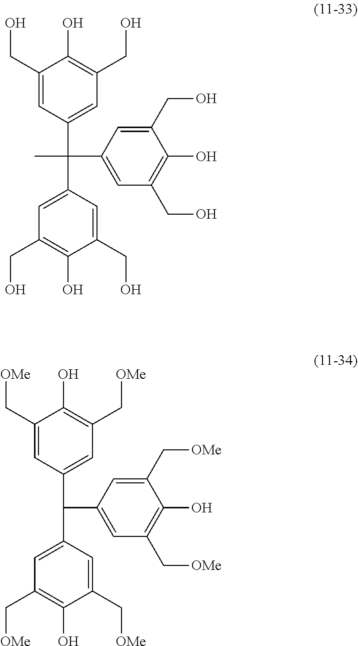

In the present embodiment, the content of the crosslinking agent is not particularly limited and is preferably 0.1 to 100 parts by mass based on 100 parts by mass of the underlayer film forming composition, more preferably 5 to 50 parts by mass, and still more preferably 10 to 40 parts by mass. By setting the content of the crosslinking agent to the above range, occurrence of a mixing event with a resist layer tends to be prevented. Also, an antireflection effect is enhanced, and film formability after crosslinking tends to be enhanced.

### [Crosslinking Promoting Agent]

The underlayer film forming composition of the present embodiment may contain a crosslinking promoting agent for accelerating crosslinking reaction (curing reaction), if required. Examples of the crosslinking promoting agent include a radical polymerization initiator.

The radical polymerization initiator may be a photopolymerization initiator that initiates radical polymerization by light, or may be a thermal polymerization initiator that initiates radical polymerization by heat. Examples of the radical polymerization initiator include at least one selected from the group consisting of a ketone-based photopolymerization initiator, an organic peroxide-based polymerization initiator and an azo-based polymerization initiator.

Examples of such radical polymerization initiators include, but are not particularly limited to, those described in International Publication No. WO 2018/016614.

In the present embodiment, the content of the crosslinking promoting agent is not particularly limited and is preferably 0.1 to 100 parts by mass based on 100 parts by mass of the underlayer film forming composition, more preferably 0.5 to 10 parts by mass, and further preferably 0.5 to 5 parts by mass. By setting the content of the crosslinking promoting agent to the above range, occurrence of a mixing event with a resist layer tends to be prevented. Also, an antireflection effect is enhanced, and film formability after crosslinking tends to be enhanced.

### [Acid Generating Agent]

The underlayer film forming composition of the present embodiment may contain an acid generating agent from the viewpoint of, for example, further accelerating crosslinking reaction by heat. An acid generating agent that generates an acid by thermal decomposition, an acid generating agent that generates an acid by light irradiation, and the like are known, any of which can be used. For example, an acid generating agent described in International Publication No. WO 2013/024779 can be used. Among these, is more preferable from the viewpoint of improving etching resistance.

The content of the acid generating agent in the underlayer film forming composition is not particularly limited and is preferably 0.1 to 50 parts by mass, and more preferably 0.5 to 40 parts by mass, based on 100 parts by mass of the underlayer film forming composition. By setting the content of the acid generating agent to the above range, crosslinking reaction tends to be enhanced and occurrence of a mixing event with a resist layer tends to be prevented.

### [Basic Compound]

The underlayer film forming composition of the present embodiment may contain a basic compound from the viewpoint of, for example, improving storage stability.

The basic compound plays a role to prevent crosslinking reaction from proceeding due to a trace amount of an acid generated from the acid generating agent, that is, a role as a quencher against the acid. The storage stability of the underlayer film forming composition is improved. Examples of such a basic compound include, but are not particularly limited to, those described in International Publication No. WO 2013/024779.

The content of the basic compound in the underlayer film forming composition of the present embodiment is not particularly limited and is preferably 0.001 to 2 parts by mass, and more preferably 0.01 to 1 part by mass, based on 100 parts by mass of the underlayer film forming composition. By setting the content of the basic compound to the above range, storage stability tends to be enhanced without excessively deteriorating crosslinking reaction.

### [Further Additive Agent]

The underlayer film forming composition of the present embodiment may also contain an additional resin and/or compound for the purpose of conferring thermosetting or light curing properties or controlling absorbance. Examples of such an additional resin and/or compound include, without particular limitations, a naphthol resin, a xylene resin naphthol-modified resin, a phenol-modified resin of a naphthalene resin; a polyhydroxystyrene, a dicyclopentadiene resin, a resin containing (meth)acrylate, dimethacrylate, trimethacrylate, tetramethacrylate, a naphthalene ring such as vinylnaphthalene or polyacenaphthylene, a biphenyl ring such as phenanthrenequinone or fluorene, or a heterocyclic ring having a heteroatom such as thiophene or indene, and a resin containing no aromatic ring; and a resin or compound containing an alicyclic structure, such as a rosin-based resin, a cyclodextrin, an adamantine(poly)ol, a tricyclodecane(poly)ol, and a derivative thereof. The film forming material for lithography of the present embodiment may also contain a publicly known additive agent. Examples of the publicly known additive agent include, but are not limited to, a thermosetting and/or light curing catalyst, a polymerization inhibitor, a flame retardant, a filler, a coupling agent, a thermosetting resin, a light curable resin, a dye, a pigment, a thickener, a lubricant, an antifoaming agent, a leveling agent, an ultraviolet absorber, a surfactant, a colorant, and a nonionic surfactant.

### [Underlayer Film for Lithography]

The underlayer film for lithography according to the present embodiment is formed from the underlayer film forming composition of the present embodiment.

### [Resist Pattern Formation Method]

The resist pattern formation method of the present embodiment comprises: an underlayer film formation step of forming an underlayer film on a substrate using the underlayer film forming composition of the present embodiment; a photoresist layer formation step of forming at least one photoresist layer on the underlayer film formed through the underlayer film formation step; and a step of irradiating a predetermined region of the photoresist layer formed through the photoresist layer formation step with radiation for development. The resist pattern formation method of the present embodiment can be used for forming various patterns, and is preferably a method for forming an insulating film pattern.

### [Circuit Pattern Formation Method]

The circuit pattern formation method of the present embodiment comprises: an underlayer film formation step of forming an underlayer film on a substrate using the underlayer film forming composition of the present embodiment; an intermediate layer film formation step of forming an intermediate layer film on the underlayer film formed through the underlayer film formation step; a photoresist layer formation step of forming at least one photoresist layer on the intermediate layer film formed through the intermediate layer film formation step; a resist pattern formation step of irradiating a predetermined region of the photoresist layer formed through the photoresist layer formation step with radiation for development, thereby forming a resist pattern; an intermediate layer film pattern formation step of etching the intermediate layer film with the resist pattern formed through the resist pattern formation step as a mask, thereby forming an intermediate layer film pattern; an underlayer film pattern formation step of etching the underlayer film with the intermediate layer film pattern formed through the intermediate layer film pattern formation step as a mask, thereby forming an underlayer film pattern; and a substrate pattern formation step of etching the substrate with the underlayer film pattern formed through the underlayer film pattern formation step as a mask, thereby forming a pattern on the substrate.

The underlayer film for lithography of the present embodiment is formed from the underlayer film forming composition of the present embodiment. The formation method is not particularly limited and a publicly known method can be applied. The underlayer film can be formed by, for example, applying the underlayer film forming composition of the present embodiment onto a substrate by a publicly known coating method or printing method such as spin coating or screen printing, and then removing an organic solvent by volatilization or the like.

It is preferable to perform baking in the formation of the underlayer film, for preventing occurrence of a mixing event with a resist upper layer film while accelerating crosslinking reaction. In this case, the baking temperature is not particularly limited and is preferably in the range of 80 to 450° C., and more preferably 200 to 400° C. The baking time is not particularly limited and is preferably in the range of 10 to 300 seconds. The thickness of the underlayer film can be arbitrarily selected according to required performance and is not particularly limited, but is preferably 30 to 20,000 nm, and more preferably 50 to 15,000 nm.

Baking is preferably carried out in an inert gas atmosphere, and for example, preferably carried out in a nitrogen atmosphere or in an argon atmosphere because the heat resistance of the underlayer film for lithography can be increased and etching resistance can also be increased.

After preparing the underlayer film, it is preferable to prepare a silicon-containing resist layer or a single-layer resist made of hydrocarbon on the underlayer film in the case of a two-layer process, and to prepare a silicon-containing intermediate layer on the underlayer film and further prepare a silicon-free single-layer resist layer on the silicon-containing intermediate layer in the case of a three-layer process. In this case, a publicly known photoresist material can be used for forming this resist layer.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high substrate etching resistance as the underlayer film in a process for exposure at 193 nm tends to increase a k value and enhance substrate reflection. However, the intermediate layer suppresses the reflection so that the substrate reflection can be 0.5% or less. The intermediate layer having such an antireflection effect is not limited, and polysilsesquioxane that crosslinks by an acid or heat in which a light absorbing group having a phenyl group or a silicon-silicon bond is introduced is preferably used for exposure at 193 nm.

Alternatively, an intermediate layer formed by chemical vapour deposition (CVD) may be used. The intermediate layer highly effective as an antireflection film prepared by CVD is not limited, and, for example, a SiON film is known. In general, the formation of an intermediate layer by a wet process such as spin coating or screen printing is more convenient and more advantageous in cost than CVD. The upper layer resist for a three-layer process may be positive type or negative type, and the same as a single-layer resist generally used can be used.

The underlayer film according to the present embodiment can also be used as an antireflection film for usual single-layer resists or an underlying material for suppression of pattern collapse. The underlayer film is excellent in etching resistance for an underlying process and can be expected to also function as a hard mask for an underlying process.

In the case of forming a resist layer from the above photoresist material, a wet process such as spin coating or screen printing is preferably used, as in the case of forming the above underlayer film. After coating with the resist material by spin coating or the like, prebaking is generally performed. This prebaking is preferably performed at 80 to 180° C. in the range of 10 to 300 seconds. Then, exposure, post-exposure baking (PEB), and development can be performed according to a conventional method to obtain a resist pattern. The thickness of the resist film is not particularly limited, and in general, is preferably 30 to 500 nm and more preferably 50 to 400 nm.

The exposure light can be arbitrarily selected and used according to the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the above method, pattern collapse is suppressed by the underlayer film. Therefore, use of the underlayer film according to the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process. The gas etching is suitably etching using oxygen gas. In addition to oxygen gas, an inert gas such as He or Ar, or CO, CO₂, NH₃, SO₂, N₂, NO₂, or H₂ gas may be added. Alternatively, the gas etching may be performed with CO, CO₂, NH₃, N₂, NO₂, or H₂ gas without the use of oxygen gas. Particularly, the latter gas is preferably used for side wall protection in order to prevent the undercut of pattern side walls.

On the other hand, gas etching is also preferably used as the etching of the intermediate layer in a three-layer process. The same gas etching as described in the above two-layer process is applicable. Particularly, it is preferable to process the intermediate layer in a three-layer process by using chlorofluorocarbon-based gas and using the resist pattern as a mask. Then, as mentioned above, for example, the underlayer film can be processed by oxygen gas etching with the intermediate layer pattern as a mask.

Herein, in the case of forming an inorganic hard mask intermediate layer film as the intermediate layer, a silicon oxide film, a silicon nitride film, or a silicon oxynitride film (SiON film) is formed by CVD, ALD, or the like. A method for forming the nitride film is not limited, and, for example, a method described in Japanese Patent Laid-Open No. 2002-334869 or WO 2004/066377 can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is suitably used as the intermediate layer. By imparting effects as an antireflection film to the resist intermediate layer film, there is a tendency that reflection can be effectively suppressed. A specific material for the polysilsesquioxane-based intermediate layer is not limited, and, for example, a material described in Japanese Patent Laid-Open No. 2007-226170 or Japanese Patent Laid-Open No. 2007-226204 can be used.

The subsequent etching of the substrate can also be performed by a conventional method. For example, the substrate made of SiO₂ or SiN can be etched mainly using chlorofluorocarbon-based gas, and the substrate made of p-Si, Al, or W can be etched mainly using chlorine- or bromine-based gas. In the case of etching the substrate with chlorofluorocarbon-based gas, the silicon-containing resist of the two-layer resist process or the silicon-containing intermediate layer of the three-layer process is stripped at the same time with substrate processing. On the other hand, in the case of etching the substrate with chlorine- or bromine-based gas, the silicon-containing resist layer or the silicon-containing intermediate layer is separately stripped and in general, stripped by dry etching using chlorofluorocarbon-based gas after substrate processing.

A feature of the underlayer film of the present embodiment is that it is excellent in etching resistance of the substrates. The substrate can be arbitrarily selected for use from publicly known ones and is not particularly limited. Examples thereof include Si, a-Si, p-Si, SiO₂, SiN, SiON, W, TiN, and Al. The substrate may be a laminate having a film to be processed (substrate to be processed) on a base material (support). Examples of such a film to be processed include various low-k films such as Si, SiO₂, SiON, SiN, p-Si, a-Si, W, W-Si, Al, Cu, and Al-Si, and stopper films thereof. A material different from that for the base material (support) is generally used. The thickness of the substrate to be processed or the film to be processed is not particularly limited and is generally preferably about 50 to 1,000,000 nm, and more preferably 75 to 50,000 nm.

### [Resist Permanent Film]

The resist permanent film of the present embodiment contains the composition of the present embodiment. The resist permanent film prepared by coating with the composition of the present embodiment is suitable as a permanent film that also remains in a final product, if required, after formation of a resist pattern. Specific examples of the permanent film include, in relation to semiconductor devices, a solder resist, a package material, an underfill material, a package adhesive layer for circuit elements and the like, and an adhesive layer between integrated circuit elements and circuit substrates, and in relation to thin displays, a thin film transistor protecting film, a liquid crystal color filter protecting film, a black matrix, and a spacer. Particularly, the resist permanent film containing the composition of the present embodiment is excellent in heat resistance and humidity resistance and furthermore, also has the excellent advantage that contamination by sublimable components is reduced. Particularly, for a display material, a material that achieves all of high sensitivity, high heat resistance, and hygroscopic reliability with reduced deterioration in image quality due to significant contamination can be obtained.

In the case of using the underlayer film forming composition of the present embodiment for resist permanent film purposes, a curing agent as well as, if required, various additive agents such as an additional resin, a surfactant, a dye, a filler, a crosslinking agent, and a dissolution promoting agent can be added and dissolved in an organic solvent to prepare a composition for resist permanent films.

The underlayer film forming composition of the present embodiment can be prepared by adding each of the above components and mixing them using a stirrer or the like. When the composition of the present embodiment contains a filler or a pigment, it can be prepared by dispersion or mixing using a dispersion apparatus such as a dissolver, a homogenizer, and a three-roll mill.

### Example 1

The present embodiment will be described in more detail with reference to synthesis examples and examples below. However, the present embodiment is not limited to these examples by any means.

### (Molecular Weight)

The weight average molecular weight (Mw) and dispersibility (Mw/Mn) of the oligomer of the present embodiment were determined under the following measurement conditions in terms of polystyrene by gel permeation chromatography (GPC) analysis.

Apparatus: Shodex GPC-101 model (a product manufactured by Showa Denko K.K.)

Column: KF-80M×3

Eluent: 1 mL/min THF

Temperature: 40° C.

### (Measurement of Softening Point)

The softening point was measured using the following equipment.

Equipment used: FP83HT dropping point and softening point measurement system manufactured by Mettler-Toledo Measurement conditions: temperature increase rate of 2° C./min

Measurement method: Measurement was made in accordance with a manual of FP83HT. Specifically, a molten sample was poured into a sample cup and allowed to cool and solidify. The top and bottom of the cup which was filled with the sample were fitted into a cartridge, which was inserted into the furnace. The temperature when the resin was softened and flown down through the orifice and the lower end of the resin was passed through the optical path was detected with a photocell as the softening point.

### (Measurement of Melt Viscosity)

The melt viscosity at 150° C. was measured using the following equipment.

Equipment used: B type viscometer DV2T manufactured by BROOKFIELD, EKO INSTRUMENTS CO., LTD.

Measurement temperature: 150° C.

Measurement method: The temperature in the furnace of the B type viscometer was set to 150° C. and a predetermined amount of sample was weighed in a cup.

The cup in which the sample was weighed was put in the furnace to melt the resin, and a spindle was inserted from the upper portion. The spindle was allowed to rotate, and the value at which the displayed viscosity value was stabilized was taken as the melt viscosity.

### (Synthesis Working Example 1) Synthesis of NAFP-AL

To a 300 mL four necked flask, 1,4-bis(chloromethyl)benzene (28.8 g, 0.148 mol, manufactured by Tokyo Kasei Kogyo Co., Ltd.), 1-naphthol (30.0 g, 0.1368 mol, manufactured by Tokyo Kasei Kogyo Co., Ltd.), and para-toluenesulfonic acid monohydrate (5.7 g, 0.029 mol, manufactured by Tokyo Kasei Kogyo Co., Ltd.) were added under nitrogen, 150.4 g of propylene glycol monomethyl ether acetate (hereinafter, abbreviated as PGMEA) was further fed into the mixture and stirred, and the temperature was raised to dissolve the mixture until reflux was confirmed, whereby polymerization was initiated. After 16 hours, the mixture was allowed to cool to 60° C., and then reprecipitated in 1,600 g of methanol.

The obtained precipitate was filtered and dried in a vacuum dryer at 60° C. for 16 hours to obtain 38.6 g of the target oligomer having a structural unit represented by the following formula (NAFP-AL). The weight average molecular weight of the obtained oligomer measured in terms of polystyrene by GPC was 2,020, and the dispersibility was 1.86. The viscosity was 0.12 Pa-s, and the softening point was 68° C.

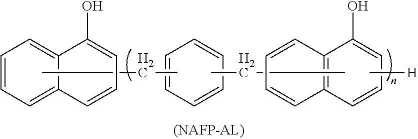

### (Synthesis Working Example 2) Synthesis of PBIF-AL

Into a four-necked flask equipped with a discharging spout at the lower part, phenol (311.9 g, 3.32 mol, manufactured by Tokyo Kasei Kogyo Co., Ltd.) and 4,4′-dichloromethylbiphenyl (200.0 g, 0.80 mol, manufactured by Tokyo Kasei Kogyo Co., Ltd.)) were fed under nitrogen, and with rising temperature, the inside of the system became homogeneous at 80° C. and generation of HCl was started. The temperature was kept at 100° C. for 3 hours, and the mixture was further subjected to heat treatment at 150° C. for 1 hour. HCl generated in a reaction was volatilized to the outside as it is and trapped in alkaline water. At this stage, there was no residue of unreacted 4,4′-dichloromethylbiphenyl and it was confirmed by gas chromatography that all of them was reacted. After completion of the reaction, HCl and unreacted phenol remained in the system were removed to the outside of the system by reducing the pressure. Eventually, the pressure reduction treatment was performed at 30 torr to 150° C., whereby residual phenol became not detected by gas chromatography. While keeping this reaction product at 150° C., about 30 g of the reaction product was slowly added dropwise from the discharging spout at the lower part of the flask onto a stainless steel pad, the temperature of which was kept at room temperature by air cooling. The reaction product was quickly cooled to 30° C. in 1 minute on the stainless steel pad to obtain a solidified polymer. For preventing the surface temperature of the stainless steel pad from rising due to the heat of the polymer, the solid was removed and the stainless steel pad was cooled by air cooling. This air cooling and solidifying operation was repeated nine times to obtain 213.3 g of an oligomer having a structural unit represented by the following formula (PBIF-AL). The weight average molecular weight of the obtained oligomer measured in terms of polystyrene by GPC was 3,100, and the dispersibility was 1.33. The viscosity was 0.06 Pa-s, and the softening point was 39° C.

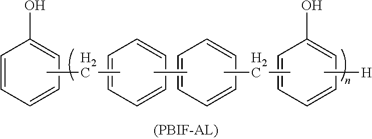

### (Synthesis Working Example 2) Synthesis of p-CBIF-AL

Into a four-necked flask equipped with a discharging spout at the lower part, p-cresol (359.0 g, 3.32 mol, manufactured by Tokyo Kasei Kogyo Co., Ltd.) and 4,4′-dichloromethylbiphenyl (200.0 g, 0.80 mol, manufactured by Tokyo Kasei Kogyo Co., Ltd.)) were fed under nitrogen, and with rising temperature, the inside of the system became homogeneous at 80° C. and generation of HCL was started. The temperature was kept at 100° C. for 3 hours, and the mixture was further subjected to heat treatment at 150° C. for 1 hour. HCl generated in a reaction was volatilized to the outside as it is and trapped in alkaline water. At this stage, there was no residue of unreacted 4,4′-dichloromethylbiphenyl and it was confirmed by gas chromatography that all of them was reacted. After completion of the reaction, HCl and unreacted phenol remained in the system were removed to the outside of the system by reducing the pressure. Eventually, the pressure reduction treatment was performed at 30 torr to 150° C., whereby residual phenol became not detected by gas chromatography. While keeping this reaction product at 150° C., about 30 g of the reaction product was slowly added dropwise from the discharging spout at the lower part of the flask onto a stainless steel pad, the temperature of which was kept at room temperature by air cooling. The reaction product was quickly cooled to 30° C. in 1 minute on the stainless steel pad to obtain a solidified polymer. For preventing the surface temperature of the stainless steel pad from rising due to the heat of the polymer, the solid was removed and the stainless steel pad was cooled by air cooling. This air cooling and solidifying operation was repeated nine times to obtain 223.1 g of an oligomer having a structural unit represented by the following formula (p-CBIF-AL). The weight average molecular weight of the obtained oligomer measured in terms of polystyrene by GPC was 2,556, and the dispersibility was 1.21. The viscosity was 0.03 Pa-s, and the softening point was 35° C.

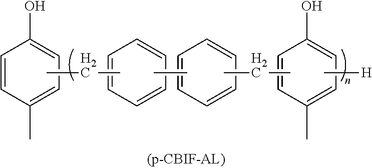

### (Synthesis Working Example 4) Synthesis of n-BBIF-AL

Into a four-necked flask equipped with a discharging spout at the lower part, 4-butylphenol (498.7 g, 3.32 mol, manufactured by Tokyo Kasei Kogyo Co., Ltd.) and 4,4′-dichloromethylbiphenyl (200.0 g, 0.80 mol, manufactured by Tokyo Kasei Kogyo Co., Ltd.)) were fed under nitrogen, and with rising temperature, the inside of the system became homogeneous at 80° C. and generation of HCL was started. The temperature was kept at 100° C. for 3 hours, and the mixture was further subjected to heat treatment at 150° C. for 1 hour. HCl generated in a reaction was volatilized to the outside as it is and trapped in alkaline water. At this stage, there was no residue of unreacted 4,4′-dichloromethylbiphenyl and it was confirmed by gas chromatography that all of them was reacted. After completion of the reaction, HCl and unreacted phenol remained in the system were removed to the outside of the system by reducing the pressure. Eventually, the pressure reduction treatment was performed at 30 torr to 150° C., whereby residual phenol became not detected by gas chromatography. While keeping this reaction product at 150° C., about 30 g of the reaction product was slowly added dropwise from the discharging spout at the lower part of the flask onto a stainless steel pad, the temperature of which was kept at room temperature by air cooling. The reaction product was quickly cooled to 30° C. in 1 minute on the stainless steel pad to obtain a solidified polymer. For preventing the surface temperature of the stainless steel pad from rising due to the heat of the polymer, the solid was removed and the stainless steel pad was cooled by air cooling. This air cooling and solidifying operation was repeated nine times to obtain 267.5 g of an oligomer having a structural unit represented by the following formula (n-BBIF-AL). The weight average molecular weight of the obtained oligomer measured in terms of polystyrene by GPC was 2,349, and the dispersibility was 1.19. The viscosity was 0.01 Pa-s, and the softening point was 30° C.

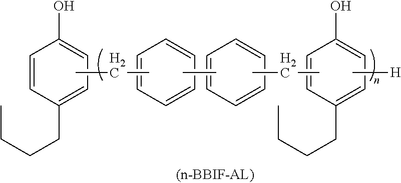

### (Synthesis Working Example 5) Synthesis of NAFBIF-AL

Into a four-necked flask equipped with a discharging spout at the lower part, 1-naphthol (478.0 g, 3.32 mol, manufactured by Tokyo Kasei Kogyo Co., Ltd.) and 4,4′-dichloromethylbiphenyl (200.0 g, 0.80 mol, manufactured by Tokyo Kasei Kogyo Co., Ltd.)) were fed under nitrogen, and with rising temperature, the inside of the system became homogeneous at 80° C. and generation of HCl was started. The temperature was kept at 100° C. for 3 hours, and the mixture was further subjected to heat treatment at 150° C. for 1 hour. HCl generated in a reaction was volatilized to the outside as it is and trapped in alkaline water. At this stage, there was no residue of unreacted 4,4′-dichloromethylbiphenyl and it was confirmed by gas chromatography that all of them was reacted. After completion of the reaction, HCl and unreacted phenol remained in the system were removed to the outside of the system by reducing the pressure. Eventually, the pressure reduction treatment was performed at 30 torr to 140° C., whereby residual phenol became not detected by gas chromatography. While keeping this reaction product at 150° C., about 30 g of the reaction product was slowly added dropwise from the discharging spout at the lower part of the flask onto a stainless steel pad, the temperature of which was kept at room temperature by air cooling. The reaction product was quickly cooled to 30° C. in 1 minute on the stainless steel pad to obtain a solidified polymer. For preventing the surface temperature of the stainless steel pad from rising due to the heat of the polymer, the solid was removed and the stainless steel pad was cooled by air cooling. This air cooling and solidifying operation was repeated nine times to obtain 288.3 g of an oligomer having a structural unit represented by the following formula (NAFBIF-AL). The weight average molecular weight of the obtained oligomer measured in terms of polystyrene by GPC was 3,450, and the dispersibility was 1.40. The viscosity was 0.15 Pa-s, and the softening point was 60° C.

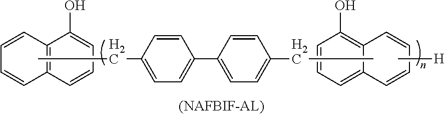

### Examples 1 to 5 and Comparative Example 1

For the above oligomer having an aralkyl structure and the phenol novolac resin (PSM4357 manufactured by Gunei Chemical Industry Co., Ltd.) as Comparative Example 1, solubility test and heat resistance evaluation shown below were carried out. The results are shown in Table 1.

### (Evaluation of Solubility)

At 23° C., the oligomer of the present embodiment was dissolved in propylene glycol monomethyl ether acetate (PGMEA) to form a 10 mass % solution. Subsequently, the solubility after leaving the solution to stand still at 10° C. for 30 days was evaluated according to the following criteria.

Evaluation A: no precipitate was visually confirmed

Evaluation C: precipitates were visually confirmed

### (Evaluation of Heat Resistance)

EXSTAR 6000 TG-DTA apparatus manufactured by SII NanoTechnology Inc. was used. About 5 mg of a sample was placed in an unsealed container made of aluminum, and the temperature was raised to 500° C. at a temperature increase rate of 10° C./min in a nitrogen gas stream (300 ml/min), thereby measuring the amount of thermogravimetric weight loss. From a practical viewpoint, evaluation A or B described below is preferable.

### <Evaluation Criteria>

A: The amount of thermogravimetric weight loss at 400° C. is less than 10%

B: The amount of thermogravimetric weight loss at 400° C. is 10% to 25%

C: The amount of thermogravimetric weight loss at 400° C. is greater than 25%

### Examples 1-1 to 5-3 and Comparative Example 1-1

Next, underlayer film forming compositions for lithography were each prepared according to the composition shown in Table 2. Next, a silicon substrate was spin coated with each of these underlayer film forming compositions for lithography, and then baked at 240° C. for 60 seconds and further at 400° C. for 120 seconds to prepare each underlayer film with a film thickness of 200 nm. Subsequently, curing properties were evaluated by the following evaluation criteria.

### [Curing Property Test]

Each underlayer film obtained from the underlayer film forming compositions for lithography of Examples 1-1 to 5-3 and Comparative Example 1-1 was immersed in PGMEA for 120 seconds and then dried at 110° C. for 60 seconds on a hot plate, and the state of each remaining film was confirmed. The results are shown in Table 2.

<Evaluation Criteria>

A: A remaining film was visually observed

C: No remaining film was visually observed

The following acid generating agent, crosslinking agent, and organic solvent were used.

Acid generating agent: a product manufactured by Midori Kagaku Co., Ltd., “di-tertiary butyl diphenyliodonium nonafluoromethanesulfonate” (in the table, designated as “DTDPI”)

Crosslinking agent: a product manufactured by Sanwa Chemical Co., Ltd., “NIKALAC MX270” (in the table, designated as “NIKALAC”)

a product manufactured by Honshu Chemical Industry Co., Ltd., “TMOM-BP” (in the table, designated as “TMOM”)

a fused aromatic ring crosslinking agent for etching resistance (in the table, designated as “fused”)

Organic solvent: propylene glycol monomethyl ether acetate (in the table, designated as “PGMEA”)

For each of the obtained underlayer films, etching test was carried out under the following conditions to evaluate etching resistance. The evaluation results are shown in Table 2.

### [Etching Test]

Etching apparatus: a product manufactured by Samco International, Inc., “RIE-10NR”

Output: 50 W

Pressure: 20 Pa

Time: 2 min

Etching gas

Ar gas flow rate:CF₄ gas flow rate:O₂ gas flow rate=50:5:5 (sccm)

### [Evaluation of Etching Resistance]

The evaluation of etching resistance was carried out by the following procedures.

First, an underlayer film containing a phenol novolac resin was prepared under the same conditions as in Example 1-1 except that a phenol novolac resin (PSM4357 manufactured by Gunei Chemical Industry Co., Ltd.) was used instead of the oligomer used in Example 1-1. Then, the above etching test was carried out for this underlayer film containing a phenol novolac resin, and the etching rate (etching speed) was measured. Next, for each of the underlayer films of Examples and Comparative Example, the above etching test was carried out, and the etching rate was measured. Then, the etching resistance for each of Examples and Comparative Example was evaluated according to the following evaluation criteria on the basis of the etching rate of the underlayer film containing a phenol novolac resin.

### <Evaluation Criteria>

S: The etching rate was less than −15% as compared with the underlayer film of novolac.

A: The etching rate was less than −10% as compared with the underlayer film of novolac.

B: The etching rate was −10% to +5% as compared with the underlayer film of novolac.

C: The etching rate was more than +5% as compared with the underlayer film of novolac.

### [Evaluation of Embedding Properties to Substrate Having Difference in Level]

The embedding properties to a substrate having difference in level were evaluated by the following procedures.

A SiO₂ substrate having a film thickness of 80 nm and a line and space pattern of 60 nm was coated with a composition for underlayer film formation for lithography, and baked at 240° C. for 60 seconds to form a 90 nm underlayer film. The cross section of the obtained film was cut out and observed under an electron microscope to evaluate the embedding properties to a substrate having difference in level. The results are shown in Table 3.

### <Evaluation Criteria>

A: The underlayer film was embedded without defects in the asperities of the SiO₂ substrate having a line and space pattern of 60 nm.

C: The asperities of the SiO₂ substrate having a line and space pattern of 60 nm had defects which hindered the embedding of the underlayer film.

### [Evaluation of Flatness]

Onto a SiO₂ substrate having difference in level on which trenches with a width of 100 nm, a pitch of 150 nm, and a depth of 150 nm (aspect ratio: 1.5) and trenches with a width of 5 μm and a depth of 180 nm (open space) were mixedly present, each of the obtained compositions for film formation was coated. Subsequently, it was calcined at 240° C. for 120 seconds under the air atmosphere to form a resist underlayer film having a film thickness of 200 nm. The shape of this resist underlayer film was observed with a scanning electron microscope (“S-4800” from Hitachi High-Technologies Corporation), and the difference between the maximum value and the minimum value of the film thickness of the resist underlayer film on the trench or space (ΔFT) was measured. The results are shown in Table 3.

### <Evaluation Criteria>

S: ΔFT<10 nm (best flatness)

A: 10 nm≤ΔFT<20 nm (good flatness)

B: 20 nm≤ΔFT<40 nm (partially good flatness)

C: 40 nm≤ΔFT (poor flatness)

TABLE 1

| | Compound or resin | Evaluation of | Evaluation of |
|---|---|---|---|
| | (part by mass) | solubility | heat resistance |
| Example 1 | NAFP-AL | A | A |
| | (10) | | |
| Example 2 | PBIF-AL | A | B |
| | (10) | | |
| Example 3 | p-CBIF-AL | A | B |
| | (10) | | |
| Example 4 | n-BBIF-AL | A | B |
| | (10) | | |
| Example 5 | NAFBIF-AL | A | A |
| | (10) | | |
| Comparative | Phenol novolac resin | A | C |
| Example 1 | (10) | | |

TABLE 2

| | Resin | Crosslinking agent | Acid generating agent | Solvent (part | Curing | Etching |
|---|---|---|---|---|---|---|
| | (part by mass) | (part by mass) | (part by mass) | by mass) | property | resistance |
| Example 1-1 | NAFP-AL (10) | — | — | PGMEA (10) | A | A |
| Example 1-2 | NAFP-AL (10) | NIKALAC (0.5) | DTDPI (0.5) | PGMEA (10) | A | B |
| Example 1-3 | NAFP-AL (10) | TMOM (0.5) | DTDPI (0.5) | PGMEA (10) | A | B |
| Example 2-1 | PBIF-AL (10) | — | — | PGMEA (10) | A | B |
| Example 2-2 | PBIF-AL (10) | NIKALAC (0.5) | DTDPI (0.5) | PGMEA (10) | A | B |
| Example 2-3 | PBIF-AL (10) | TMOM (0.5) | DTDPI (0.5) | PGMEA (10) | A | B |
| Example 3-1 | p-CBIF-AL (10) | — | — | PGMEA (10) | A | B |
| Example 3-2 | p-CBIF-AL (10) | NIKALAC (0.5) | DTDPI (0.5) | PGMEA (10) | A | B |
| Example 3-3 | p-CBIF-AL (10) | TMOM (0.5) | DTDPI (0.5) | PGMEA (10) | A | B |
| Example 4-1 | n-BBIF-AL (10) | — | — | PGMEA (10) | A | B |
| Example 4-2 | n-BBIF-AL (10) | NIKALAC (0.5) | DTDPI (0.5) | PGMEA (10) | A | B |
| Example 4-3 | n-BBIF-AL(10) | TMOM (0.5) | DTDPI (0.5) | PGMEA (10) | A | B |
| Example 5-1 | NAFBIF-AL (10) | — | — | PGMEA (10) | A | A |
| Example 5-2 | NAFBIF-AL (10) | NIKALAC (0.5) | DTDPI (0.5) | PGMEA (10) | A | B |
| Example 5-3 | NAFBIF-AL (10) | TMOM (0.5) | DTDPI (0.5) | PGMEA (10) | A | B |
| Comparative | Phenol novolac | — | — | PGMEA (10) | C | — |
| Example 1-1 | resin (10) | | | | | |

TABLE 3

| | Resin | Crosslinking agent | Acid generating agent | Solvent | Embedding | |
|---|---|---|---|---|---|---|
| | (part by mass) | (part by mass) | (part by mass) | (part by mass) | property | Flatness |
| Example 1-1 | NAFP-AL (10) | — | — | PGMEA (10) | B | B |
| Example 1-2 | NAFP-AL (10) | NIKALAC (0.5) | DTDPI (0.5) | PGMEA (10) | B | B |
| Example 1-3 | NAFP-AL (10) | TMOM (0.5) | DTDPI (0.5) | PGMEA (10) | A | A |
| Example 2-1 | PBIF-AL (10) | — | — | PGMEA (10) | A | A |
| Example 2-2 | PBIF-AL (10) | NIKALAC (0.5) | DTDPI (0.5) | PGMEA (10) | A | A |
| Example 2-3 | PBIF-AL (10) | TMOM (0.5) | DTDPI (0.5) | PGMEA (10) | S | S |
| Example 3-1 | p-CBIF-AL (10) | — | — | PGMEA (10) | A | A |
| Example 3-2 | p-CBIF-AL (10) | NIKALAC (0.5) | DTDPI (0.5) | PGMEA (10) | A | S |
| Example 3-3 | p-CBIF-AL (10) | TMOM (0.5) | DTDPI (0.5) | PGMEA (10) | S | S |
| Example 4-1 | n-BBIF-AL (10) | — | — | PGMEA (10) | A | A |
| Example 4-2 | n-BBIF-AL (10) | NIKALAC (0.5) | DTDPI (0.5) | PGMEA (10) | S | S |
| Example 4-3 | n-BBIF-AL (10) | TMOM (0.5) | DTDPI (0.5) | PGMEA (10) | S | S |
| Example 5-1 | NAFBIF-AL (10) | — | — | PGMEA (10) | B | B |
| Example 5-2 | NAFBIF-AL (10) | NIKALAC (0.5) | DTDPI (0.5) | PGMEA (10) | B | B |
| Example 5-3 | NAFBIF-AL (10) | TMOM (0.5) | DTDPI (0.5) | PGMEA (10) | A | A |
| Comparative | Phenol novolac | — | — | PGMEA (10) | A | B |
| Example 1-1 | resin (10) | | | | | |

### Examples 4 to 9

A SiO₂ substrate with a film thickness of 300 nm was coated with the solution of the underlayer film forming material for lithography prepared in each of the above Examples 1-1 to 5-3, and baked at 240° C. for 60 seconds and further at 400° C. for 120 seconds to form each underlayer film with a film thickness of 70 nm. This underlayer film was coated with a resist solution for ArF and baked at 130° C. for 60 seconds to form a photoresist layer with a film thickness of 140 nm. The ArF resist solution used was prepared by compounding 5 parts by mass of a compound represented by the formula (11) given below, 1 part by mass of triphenylsulfonium nonafluoromethanesulfonate, 2 parts by mass of tributylamine, and 92 parts by mass of PGMEA. For the compound represented by the formula (11) given below, 4.15 g of 2-methyl-2-methacryloyloxyadamantane, 3.00 g of methacryloyloxy-y-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula.

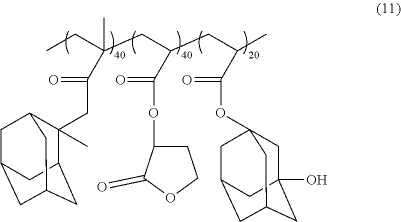

The numbers in the above formula (11) indicate the ratio of each constitutional unit.

Subsequently, the photoresist layer was exposed using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a positive type resist pattern.

Defects of the obtained resist patterns of 55 nm L/S (1:1) and 80 nm L/S (1:1) were observed, and the results are shown in Table 4. In the table, “good” means that no major defects were found in the formed resist pattern, and “poor” means that major defects were found in the formed resist pattern.

### Comparative Example 2

The same operations as in Example 7 were carried out except that no underlayer film was formed so that a photoresist layer was formed directly on a SiO₂ substrate to obtain a positive type resist pattern. The results are shown in Table 4.

TABLE 4

| | Underlayer | | | Resist pattern |
|---|---|---|---|---|
| | film forming | Resolution | Sensitivity | shape after |
| | material | (nmL/S) | (μC/cm²) | development |
| Example 4 | Example 1-1 | 55 | 10 | Good |
| Example 5 | Example 1-2 | 55 | 10 | Good |
| Example 6 | Example 1-3 | 55 | 10 | Good |
| Example 7 | Example 2-1 | 55 | 10 | Good |
| Example 8 | Example 2-2 | 55 | 10 | Good |
| Example 9 | Example 2-3 | 55 | 10 | Good |
| Example 10 | Example 3-1 | 55 | 10 | Good |
| Example 11 | Example 3-2 | 55 | 10 | Good |
| Example 12 | Example 3-3 | 55 | 10 | Good |
| Example 13 | Example 4-1 | 55 | 10 | Good |
| Example 14 | Example 4-2 | 55 | 10 | Good |
| Example 15 | Example 4-3 | 55 | 10 | Good |
| Example 16 | Example 5-1 | 55 | 10 | Good |
| Example 17 | Example 5-2 | 55 | 10 | Good |
| Example 18 | Example 5-3 | 55 | 10 | Good |
| Comparative | — | 80 | 26 | Poor |
| Example 2 | | | | |

As is evident from Table 1, Examples 1 to 5 using any of the oligomers having an aralkyl structure of the present embodiment were confirmed to be good in terms of any of solubility and heat resistance. On the other hand, in Comparative Example 1 using the phenol novolac resin was poor in heat resistance.

As is evident from Table 2 and Table 3, the underlayer film formed using any of underlayer film forming compositions for lithography comprising an oligomer having an aralkyl structure of the present embodiment (Example 1-1 to Example 5-3) were confirmed to be not only excellent in curing properties and etching resistance, but also good in terms of both embedding properties and smoothing properties, as compared with the underlayer film comprising the phenol novolac resin of Comparative Example 1-1. The underlayer film self-cures without the need for a crosslinking agent and an acid generating agent, so that it can express particularly excellent flatness.

As is evident from Table 4, Examples 4 to 18 using any of the oligomers having an aralkyl structure of the present embodiment were confirmed to have a good resist pattern shape after development and have no major defects found. Further, each of Examples 4 to 18 was confirmed to be significantly excellent in both resolution and sensitivity, as compared with Comparative Example 2 which does not form an underlayer film. Here, a good resist pattern shape after development indicates that the underlayer film forming materials for lithography used in Examples 4 to 18 have good adhesiveness to a resist material (photoresist material and the like).

### Examples 19 to 33

A SiO₂ substrate with a film thickness of 300 nm was coated with each solution of the underlayer film forming materials for lithography of Examples 1-1 to 5-3, and baked at 240° C. for 60 seconds and further at 400° C. for 120 seconds to form each underlayer film with a film thickness of 80 nm. This underlayer film was coated with a silicon-containing intermediate layer material and baked at 200° C. for 60 seconds to form an intermediate layer film with a film thickness of 35 nm. This intermediate layer film was further coated with the above resist solution for ArF and baked at 130° C. for 60 seconds to form a photoresist layer with a film thickness of 150 nm. The silicon-containing intermediate layer material used was the silicon atom-containing polymer described in <Synthesis Example 1> of Japanese Patent Laid-Open No. 2007-226170. Subsequently, the photoresist layer was mask exposed using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a 55 nm L/S (1:1) positive type resist pattern. Then, the silicon-containing intermediate layer film (SOG) was dry etched with the obtained resist pattern as a mask using RIE-10NR manufactured by Samco International, Inc. Subsequently, dry etching of the underlayer film with the obtained silicon-containing intermediate layer film pattern as a mask and dry etching of the SiO₂ film with the obtained underlayer film pattern as a mask were performed in order.

Respective etching conditions are as shown below.

Conditions for etching of resist intermediate layer film with resist pattern
Output: 50 W
Pressure: 20 Pa
Time: 1 min
Etching gas
Ar gas flow rate:CF₄ gas flow rate:O₂ gas flow rate=50:8:2 (sccm)

Conditions for etching of resist underlayer film with resist intermediate film pattern
Output: 50 W
Pressure: 20 Pa
Time: 2 min
Etching gas
Ar gas flow rate:CF₄ gas flow rate:O₂ gas flow rate=50:5:5 (sccm)

Conditions for etching of SiO₂ film with resist underlayer film pattern
Output: 50 W
Pressure: 20 Pa
Time: 2 min
Etching gas
Ar gas flow rate:C₅F₁₂ gas flow rate:C₂F₆ gas flow rate:O₂ gas flow rate=50:4:3:1 (sccm)

### [Evaluation]

The pattern cross section (that is, the shape of the SiO₂ film after etching) obtained as described above was observed by using a product manufactured by Hitachi, Ltd., “electron microscope (S-4800)”. The observation results are shown in Table 5. In the table, “good” means that no major defects were found in the formed pattern cross section, and “poor” means that major defects were found in the formed pattern cross section.

TABLE 5

| | Underlayer film | Shape of | |
|---|---|---|---|
| | forming material | SiO2 film | Appearance |
| Example 19 | Example 1-1 | Rectangle | Good |
| Example 20 | Example 1-2 | Rectangle | Good |
| Example 21 | Example 1-3 | Rectangle | Good |
| Example 22 | Example 2-1 | Rectangle | Good |
| Example 23 | Example 2-2 | Rectangle | Good |
| Example 24 | Example 2-3 | Rectangle | Good |
| Example 25 | Example 3-1 | Rectangle | Good |
| Example 26 | Example 3-2 | Rectangle | Good |
| Example 27 | Example 3-3 | Rectangle | Good |
| Example 28 | Example 4-1 | Rectangle | Good |
| Example 29 | Example 4-2 | Rectangle | Good |
| Example 30 | Example 4-3 | Rectangle | Good |
| Example 31 | Example 5-1 | Rectangle | Good |
| Example 32 | Example 5-2 | Rectangle | Good |
| Example 33 | Example 5-3 | Rectangle | Good |

### (Example 34) Purification of NAFBIF-AL with Acid

In a four necked flask (capacity: 1000 mL, with a detachable bottom), 150 g of a solution (10% by mass) formed by dissolving NAFBIF-AL obtained in Synthesis Working Example 5 in PGMEA was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand for 30 minutes and the aqueous phase was removed. After repeating this operation three times, the residual water and PGMEA were concentrated and removed by heating to 80° C. and reducing the pressure in the flask to 200 hPa or less. By diluting with PGMEA of EL grade (a reagent manufactured by Kanto Chemical Co., Inc.) such that the concentration of NAFBIF-AL in PGMEA solution was adjusted to 10% by mass, a PGMEA solution of NAFBIF-AL with a reduced metal content was obtained.

### (Comparative Example 3) Purification of NAFBIF-AL with Ultrapure Water

In the same manner as of Example 34 except that ultrapure water was used instead of the aqueous oxalic acid solution, and by adjusting the concentration to 10% by mass, a PGMEA solution of NAFBIF-AL was obtained.

For the 10 mass % NAFBIF-AL solution in PGMEA before the treatment, and the solutions obtained in Example 34 and Comparative Example 3, the contents of various metals were measured by ICP-MS. The measurement results are shown in Table 6.

TABLE 6

| | Metal content (ppb) | | | | | |
|---|---|---|---|---|---|---|
| | Na | Mg | K | Fe | Cu | Zn |
| Before | >99 | 22.2 | >99 | >99 | 11.5 | 10.0 |
| treatment | | | | | | |
| NAFBIF-AL | | | | | | |
| Example 34 | 1.8 | 1.1 | 0.5 | 1.6 | 0.2 | 0.2 |
| Comparative | 2.5 | 1.5 | 1.2 | >99 | 2.3 | 3.3 |
| Example 3 | | | | | | |

1. An underlayer film forming composition for lithography, comprising:
a: an oligomer having an aralkyl structure represented by the following formula (1-0); and
b: a solvent, 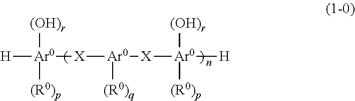
wherein
Ar⁰ represents a phenylene group, a naphthylene group, an anthrylene group, a phenanthrylene group, a pyrylene group, a fluorirene group, a biphenylene group, a diphenylmethylene group, or a terphenylene group;
R⁰ is a substituent on Ar⁰, and each R⁰ is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
X represents a linear or branched alkylene group;
n represents an integer of 1 to 500;
r represents an integer of 1 to 3;
p represents a positive integer; and
q represents a positive integer.

2. The underlayer film forming composition for lithography according to claim 1, wherein the oligomer having an aralkyl structure represented by the formula (1-0) is represented by the following formula (1-1): 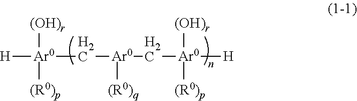
wherein
Ar⁰ represents a phenylene group, a naphthylene group, an anthrylene group, a phenanthrylene group, a pyrylene group, a fluorirene group, a biphenylene group, a diphenylmethylene group, or a terphenylene group;
R⁰ is a substituent on Ar⁰, and each R⁰ is independently the same or different groups and represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
n represents an integer of 1 to 500;
r represents an integer of 1 to 3;
p represents a positive integer; and
q represents a positive integer.

3. The underlayer film forming composition for lithography according to claim 2, wherein the oligomer having an aralkyl structure represented by the formula (1-1) is represented by the following formula (1-2): 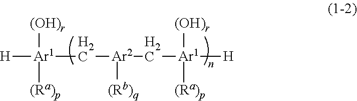
wherein
Ar² represents a phenylene group, a naphthylene group, or a biphenylene group;
Ar¹ represents a naphthylene group or a biphenylene group when Ar² is a phenylene group;
Ar¹ represents a phenylene group, a naphthylene group, or a biphenylene group when Ar² is a naphthylene group or a biphenylene group;
R^{a} is a substituent on Ar¹, and each R^{a} is independently the same or different groups;
R^{a} represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
R^{b} is a substituent on Ar², and each R^{b} is independently the same or different groups;
R^{b} represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
n represents an integer of 1 to 500;
r represents an integer of 1 to 3;
p represents a positive integer; and
q represents a positive integer.

4. The underlayer film forming composition for lithography according to claim 3, wherein
Ar² represents a phenylene group, a naphthylene group, or a biphenylene group;
Ar¹ represents a biphenylene group when Ar² is a phenylene group;
Ar¹ represents a phenylene group, a naphthylene group, or a biphenylene group when Ar² is a naphthylene group or a biphenylene group;
R^{a} represents a hydrogen atom or an alkyl group having 1 to 30 carbon atoms and optionally having a substituent; and
R^{b} represents a hydrogen atom or an alkyl group having 1 to 30 carbon atoms and optionally having a substituent.

5. The underlayer film forming composition for lithography according to claim 3, wherein the oligomer having an aralkyl structure represented by the formula (1-2) is represented by the following formula (2) or formula (3): 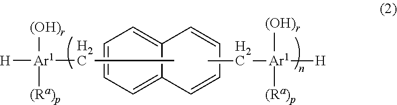
wherein, Ar¹, R^{a}, r, p, and n are as defined in the formula (1-2), and 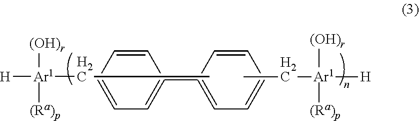
wherein, Ar¹, R^{a}, r, p, and n are as defined in the formula (1-2).

6. The underlayer film forming composition for lithography according to claim 5, wherein the oligomer having an aralkyl structure represented by the formula (2) is represented by the following formula (4): 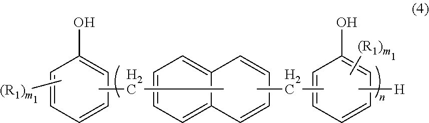
wherein
each R₁ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
m₁ represents an integer of 1 to 3; and
n represents an integer of 1 to 50.

7. The underlayer film forming composition for lithography according to claim 5, wherein the oligomer having an aralkyl structure represented by the formula (3) is represented by the following formula (5): 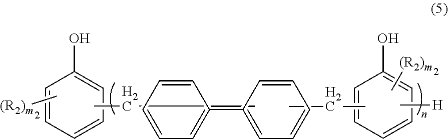
wherein
each R₂ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
m₂ represents an integer of 1 to 3; and
n represents an integer of 1 to 50.

8. The underlayer film forming composition for lithography according to claim 5, wherein the oligomer having an aralkyl structure represented by the formula (2) is represented by the following formula (6): 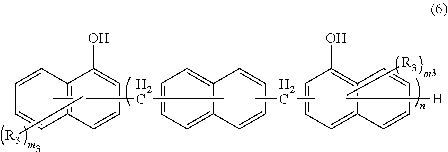
wherein
each R₃ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
m₃ represents an integer of 1 to 5; and
n represents an integer of 1 to 50.

9. The underlayer film forming composition for lithography according to claim 5, wherein the oligomer having an aralkyl structure represented by the formula (3) is represented by the following formula (7): 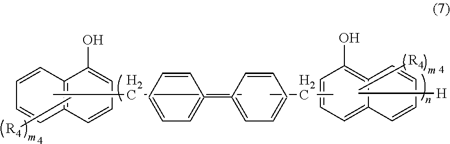
wherein
each R₄ independently represents a hydrogen atom, an alkyl group having 1 to 30 carbon atoms and optionally having a substituent, an aryl group having 6 to 30 carbon atoms and optionally having a substituent, an alkenyl group having 2 to 30 carbon atoms and optionally having a substituent, an alkynyl group having 2 to 30 carbon atoms and optionally having a substituent, an alkoxy group having 1 to 30 carbon atoms and optionally having a substituent, an acyl group having 1 to 30 carbon atoms and optionally having a substituent, a group including a carboxyl group having 1 to 30 carbon atoms and optionally having a substituent, an amino group having 0 to 30 carbon atoms and optionally having a substituent, a halogen atom, a cyano group, a nitro group, a thiol group, or a heterocyclic group;
m₄ represents an integer of 1 to 5; and
n represents an integer of 1 to 50.

10. The underlayer film forming composition for lithography according to claim 1, further comprising an acid generating agent.

11. The underlayer film forming composition for lithography according to claim 1, further comprising a crosslinking agent.

12. An underlayer film for lithography formed by using the underlayer film forming composition for lithography according to claim 1.

13. A method for forming a resist pattern, comprising the steps of:
forming an underlayer film on a substrate using the underlayer film forming composition for lithography according to claim 1;
forming at least one photoresist layer on the underlayer film; and
irradiating a predetermined region of the photoresist layer with radiation for development.

14. A method for forming a circuit pattern comprising the steps of:
forming an underlayer film on a substrate using the underlayer film forming composition for lithography according to claim 1;
forming an intermediate layer film on the underlayer film by using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask;
etching the underlayer film with the obtained intermediate layer film pattern as an etching mask; and
etching the substrate with the obtained underlayer film pattern as an etching mask, thereby forming a pattern on the substrate.

15. A purification method comprising the steps of:
obtaining an organic phase by dissolving the oligomer having an aralkyl structure according to claim 1 in a solvent; and
extracting impurities in the oligomer by bringing the organic phase into contact with an acidic aqueous solution,
wherein
the solvent used in the step of obtaining the organic phase contains a solvent that does not inadvertently mix with water.
